(19) United States
(12) Patent Application Publication
(10) Pub. No.: US 2003/0085715 A1
(43) Pub. Date: May 8, 2003

(54) System and method for locating a fault on ungrounded and high-impedance grounded power systems

(76) Inventors: David Lubkeman, Raleigh, NC (US); Michael J. Gorman, Fitchburg, WI (US); David G. Hart, Raleigh, NC (US)

Correspondence Address: Woodcock Washburn Kurtz, Mackiewicz & Norris LLP, One Liberty Place - 46th Floor, Philadelphia, PA, 19103, US

(21) Appl. No.: 09/929,933

(22) Filed: Aug. 15, 2001

(51) Int. Cl. G01R 31/14

(52) U.S. Cl. 324/509

(57) ABSTRACT

A fault is located in a power distribution system having a line frequency. The power distribution system includes a plurality of phases, at least one feeder, and each feeder includes at least one segment. The fault is located by detecting a faulted phase from the plurality of phases of the power distribution system. A measurement signal having a measurement frequency is injected into the detected faulted phase, the measurement frequency being a different frequency than the line frequency. The fault location is determined for a selected segment based on at least one measured residual current corresponding to the injected signal and a predetermined relative impedance of the power distribution system.

### FIELD OF THE INVENTION

The present invention relates to a system and method for locating a fault in a power system, more particularly, an ungrounded or high-impedance grounded power distribution system.

### BACKGROUND OF THE INVENTION

Power distribution systems carry current from transformers and/or generating sources to electrical loads. A power distribution system typically includes three phases, however, a power distribution system may also include one phase, or some other number of phases. Additionally, the power distribution system may be grounded, ungrounded, or high impedance grounded.

Ungrounded and high-impedance grounded distribution systems are used in a number of industrial power distribution systems. The advantage of these systems is that they can continue operation after a single ground fault occurs, thereby eliminating the need for immediate shutdown. Unfortunately, ground faults are hard to locate in ungrounded or high-impedance grounded systems since the ground current for the first fault is much smaller than the load currents. Additionally, some faults are intermittent, making them even more difficult to locate.

A number of companies make devices for the detection of faults on ungrounded or high-impedance power distribution systems. One common method is the ground fault indicator—a set of indicator lamps or voltage measurements. A low-voltage reading or a dim lamp is indicative of a phase-to-ground fault. For detection of faults on ungrounded systems, insulation monitoring is also used. Insulation monitoring devices measure the resistance between the phases and ground. Once the resistance drops below a set threshold, an indication is given. However, these types of devices do not determine a fault location; rather, these devices only indicate the occurrence of a fault and indicate the phase on which the fault has occurred.

One system for fault location on ungrounded or high-impedance grounded power distribution systems utilizes a high-frequency current-injection source in conjunction with ground fault detectors to locate a fault, as disclosed in U.S. Pat. No. 6,154,036, issued Nov. 28, 2000, entitled “Ground Fault Location System and Ground Fault Detector Therefor”, and in U.S. patent application Ser. No. 09/272,017, filed Mar. 18, 1999, entitled “Ground Fault Location System and Ground Fault Detector Therefor”, both of which are hereby incorporated by reference in their entirety. However, these systems do not determine a specific fault location; rather, these systems provide a general fault location. That is, the power distribution system is divided into sections and the system determines which section is faulted.

Yet another system measures current and voltage of a power distribution system and performs a known two-terminal fault location technique. However, the measured voltages are often too small to measure reliably, which may introduce errors into the determined fault location. Moreover, standard relays typically do not have many input channels for voltages. Therefore, non-standard relays may be required to implement this system. Further, this system uses actual impedance values which are determined prior to system operation. This can take a great deal of time and can disrupt the operation of an industrial site significantly. Moreover, the measurements may not be accurate because the measured impedance is typically very low; often low enough that the contact resistance of an impedance measuring device may introduce significant errors into the measurement.

Fault location is also possible using directional measurements as in a high-voltage transmission system, but these products are generally too complex and expensive for use in an industrial environment.

Therefore, a need exists for a system and method for calculating a fault location in an ungrounded or high-impedance grounded power distribution system without relying on voltage measurements and without relying on actual impedance values. The present invention satisfies this need.

### SUMMARY OF THE PRESENT INVENTION

The present invention is directed to a system and method for calculating a fault location in a power distribution system based on an injected signal, a network model, at least one current measurement corresponding to the injected signal, and at least one predetermined relative impedance.

According to an aspect of the invention, a fault is located in a power distribution system having a line frequency, the power distribution system including a plurality of phases, the power distribution system including at least one feeder, each of which includes at least one segment. The fault is located by detecting a faulted phase from the plurality of phases of the power distribution system. A measurement signal having a measurement frequency is injected into the detected faulted phase, the measurement frequency being a different frequency than the line frequency. The fault location is determined for a selected segment based on at least one measured residual current corresponding to the injected signal and a predetermined relative impedance of the power distribution system.

According to another aspect of the present invention, a fault may be located for both looped and radial power distribution systems. A looped power distribution system includes a sending node and a receiving node. For such a looped power distribution system, a faulted feeder is determined based on the injected measurement signal and a fault location is selected if the fault location is within a predetermined range. In more detail, a feeder is selected and a first residual current from the sending node to the selected feeder and a second residual current from the receiving node to the selected feeder are measured. The first residual current and the second residual current are summed. The selected feeder is determined to be the faulted feeder if the summed residual currents are greater than a predetermined current.

According to a further aspect of the present invention, determining a fault location for the selected segment of the faulted feeder further includes modeling non-faulted feeders as an equivalent feeder, modeling the selected segment as having a first impedance of m*Z and a second impedance of (1−m)*Z, where m is the relative distance of the fault location on the selected segment, and Z is the impedance of the selected segment at the measurement frequency, modeling the power distribution system with at least one loop equation for the modeled equivalent feeder and the modeled selected segment, and determining a fault location based on the relative distance and at least one loop equation.

For a radial power distribution system, each feeder includes one segment, and each feeder includes a sending node. To calculate a fault location a reference impedance is connected from the sending node to ground upon the injecting a measurement signal. Then the fault location is determined by measuring a current in the reference impedance, measuring a fault current; and determining a fault location based upon the measured fault current and the measured current in the reference impedance.

According to a further aspect of the present invention, feeders may be modeled by a set of characteristic relative impedances. The characteristic relative impedances may be determined by placing test faults on the power distribution system, measuring currents, and performing a least-squares error fit based on the measured currents. The characteristic relative impedance can then be used in later fault calculations.

According to a yet further aspect of the present invention, in a looped power system, currents may be measured for all feeders and a least-square fit used to determine a fault location.

These and other features of the present invention will be more fully set forth hereinafter.

### BRIEF DESCRIPTION OF THE DRAWINGS

The present invention is further described in the detailed description that follows, by reference to the noted plurality of drawings by way of non-limiting embodiments of the present invention, in which like reference numerals represent similar elements throughout the several views of the drawings, and wherein:

FIG. 1 is a diagram of an exemplary looped power distribution system, with which the present invention may be employed;

FIG. 2 is a block diagram of a system in accordance with one embodiment of the present invention;

FIG. 3 is a diagram of the system of FIG. 2 applied to the power distribution system of FIG. 1, in accordance with one embodiment of the present invention;

FIG. 4 is a flow chart of a method in accordance with one embodiment of the present invention and illustrating the operation of the system of FIG. 2;

FIG. 5 is a diagram of the system of FIG. 2 applied to the power distribution system of FIG. 1 illustrating a faulted power feeder and an equivalent circuit representation of other power feeders, in accordance with one embodiment of the present invention;

FIG. 6 is a diagram of an exemplary radial power distribution system, with which the present invention may be employed;

FIG. 7 is a diagram of the system of FIG. 2 applied to the power distribution system of FIG. 6, in accordance with another embodiment of the present invention;

FIG. 8 is a diagram of the system of FIG. 2 applied to the power distribution system of FIG. 6 having a fault, in accordance with one embodiment of the present invention;

FIG. 9 is a diagram of an exemplary radial power distribution system illustrating a faulted feeder, in accordance with one embodiment of the present invention;

FIG. 10 is a flow chart of a method in accordance with another embodiment of the present invention and illustrating the operation of the system of FIG. 2;

FIG. 11 is a diagram of a radial power distribution system having one segment having a fixed impedance and another segment having a relative characteristic relative impedance, with which the present invention may be employed;

FIG. 12 is a diagram of a radial power distribution system having a forked configuration, with which the present invention may be employed; and

FIG. 13 is a diagram of another looped power distribution system modeled for determining a fault location using a least-squares error criterion, in accordance with one embodiment of the present invention.

### DETAILED DESCRIPTION OF THE ILLUSTRATIVE EMBODIMENTS

The present invention is directed to a system and method for calculating a fault location in a power distribution system based on an injected signal, a network model, at least one current measurement corresponding to the injected signal and at least one predetermined relative impedance.

Certain terminology may be used in the following description for convenience only and is not considered to be limiting. For example, the words “left”, “right”, “upper”, and “lower” designate directions in the drawings to which reference is made. Likewise, the words “inwardly” and “outwardly” are directions toward and away from, respectively, the geometric center of the referenced object. The terminology includes the words above specifically mentioned, derivatives thereof, and words of similar import.

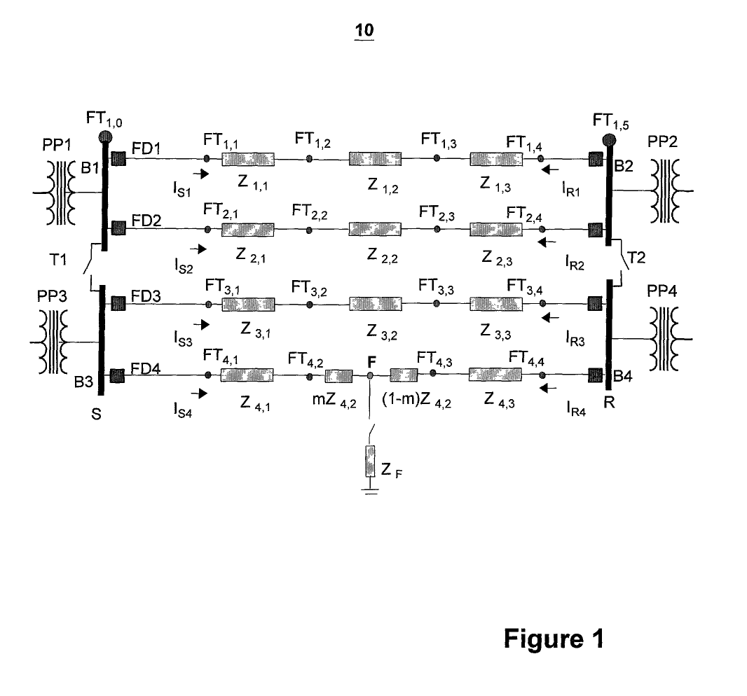

FIG. 1 illustrates an exemplary looped power distribution system having a fault node F. As shown in FIG. 1, the power distribution system 10 includes a sending node S and a receiving node R. Sending node S includes bus B1 and bus B3. Transformer PP1 is connected to bus B1 and transformer PP3 is connected bus B3. Bus B1 and bus B3 may be connected by tie breaker T1. Tie breaker T1 is normally closed, although tie breaker T1 may be open. Receiving node R includes bus B2 and bus B4. Transformer PP2 is connected to bus B2 and transformer PP4 is connected to bus B4. Bus B2 and bus B4 may be connected by tie breaker T2. Tie breaker T2 is normally closed, although tie breaker T2 may be open. It should be appreciated that the examples below assume that tie breaker T1 and tie breaker T2 are closed, however, the present invention is not so limited. Feeders FD1-FD4 connect sending node S to receiving node R. Feeders FD1-FD4 are divided into segments by feeder taps FT. Power distribution system 10 operates at a line frequency of, for example, 60 Hz.

While the exemplary looped power distribution system of FIG. 1 is shown as including four feeder and three segments per feeder, it should be appreciated that the present invention may be applied to any looped power distribution system with any number of feeders and any number of segments per feeder.

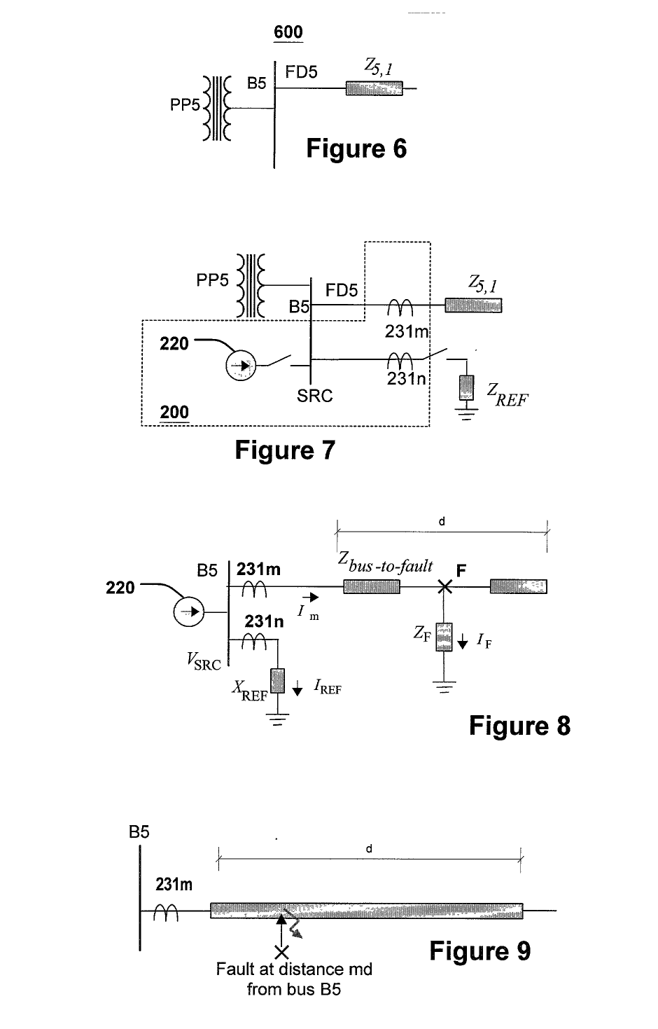

The present invention may be applied to a three phase power distribution system or a two phase power distribution system, as long as the loads are connected from line to line, rather than from line to neutral. Further, the present invention may be applied to a single phase system as long as the neutral and ground of the single phase system are separated. Also, the present invention may be applied to both looped and radial power distribution topographies. A looped power distribution system supplies power to a load from two directions. For example, if a load is electrically connected to a bus, the load may receive power from either side of the connection to the bus. FIG. 1 illustrates an exemplary looped power distribution system. The present invention may also be applied to a radial power distribution system. A radial power distribution system supplies power to a load from one direction. That is, if a load is electrically connected to a bus, the load receives power from only one side of the connection to the bus. FIG. 6 illustrates an exemplary radial power distribution system.

In order to describe the invention, the following naming conventions will be used. Upper case letter conventions are described in Table 1.

TABLE 1

| | |
|---|---|
| V | Voltage, a complex value |
| I | Current, complex value |
| Z | Impedance, complex value |
| FT | Feeder tap node (test fault location) |
| F | Fault point, faulted node, or fault location |
| B | Bus |
| FD | Feeder |
| Re{X} | Real portion of parameter X |
| Im{X} | Imaginary portion of parameter X |

A subscripted letter or numeral designates a location in the power distribution system, as described below in Table 2.

TABLE 2

| | |
|---|---|
| X_{SRC} | parameter X at source node |
| X_{S} | parameter X at sending node |
| X_{R} | parameter X at receiving node |
| FT_{a,b} | Feeder number a, tap number b (for Feeder tap nodes) |
| Z_{e,f} | Impedance of segment f of feeder e (for impedance Z) |
| Z_{SRC,g} | Impedance from source node to node g |
| I_{S,h} | Current from sending node to feeder h |

The relative (i.e., the percentage) distance to the fault within a power system feeder segment is designated by m. The variable m is used to represent the position of the fault along a feeder segment. For a specific feeder, a single subscript of mₓ indicates a feeder segment. For example, m₂ indicates the second segment of a feeder. An additional subscript may be used to indicate fault measurement number as required by context.

The distance of a feeder segment is represented by the variable d. A subscript of d_{x,y} indicates a feeder and segment. For example, d_{4,2} indicates the length of the second segment of feeder four. The location of a fault is given by the product of m and d.

As shown in FIG. 1, feeder FD1 is connected between bus B1 and bus B2. Feeder FD1 includes three segments from left to right having impedances Z_{1,1}, Z_{1,2}, and Z_{1,3}, respectively. Similarly, feeder FD2 is connected between bus B1 and bus B2. Feeder FD2 includes three segments from left to right having impedances Z_{2,1}, Z_{2,2}, and Z_{2,3}, respectively. Feeder FD3 is connected between bus B3 and bus B4. Feeder FD3 includes three segments from left to right having impedances Z_{3,1}, Z_{3,2}, and Z_{3,3}, respectively. Similarly, feeder FD4 is connected between bus B3 and bus B4. Feeder FD4 includes three segments from left to right having impedances Z_{4,1}, Z_{4,2}, and Z_{4,3}, respectively. These impedances are understood to be impedances at the measurement frequency.

Each feeder FD can be modeled by series impedance (e.g., resistance and reactance) segments. In the power distribution system 10 shown in FIG. 1, three segments are used to model each feeder. The two outer segments may represent the cable that ties transformers to a plant bus duct and the inner segment may represent the plant bus duct itself. Feeders are typically fed by multiple transformers (e.g., transformers PP1-PP4) to minimize voltage drops due to large load currents, such as those drawn by arc welders, and the like.

Currents flow through power distribution system 10. Current I_{S1} flows from sending node S to feeder FD1 and current I_{R1} flows from receiving node R to feeder FD1. Current I_{S2} flows from sending node S to feeder FD2 and current I_{R2} flows from receiving node R to feeder FD2. Current I_{S3} flows from sending node S to feeder FD3 and current I_{R3} flows from receiving node R to feeder FD3. Current I_{S4} flows from sending node S to feeder FD4 and current I_{R4} flows from receiving node R to feeder FD4.

Power distribution system 10 includes a fault node F on the second segment of the fourth feeder (i.e., the segment between feeder tap FT_{4,2} and feeder tap FT_{4,3}, having a total impedance of Z_{4,2}). The fault node F divides the impedance from feeder tap FT_{4,2} to feeder tap FT_{4,3}, into two impedances. The first impedance is (m*Z_{4,2}) and the second impedance is ((1−m)*Z_{4,2}).

In one embodiment of the present invention, for a relative distance of one from feeder tap FT_{4,2} to feeder tap FT_{4,3}, fault node F lies a relative distance of m away from feeder tap FT_{4,2}, and a relative distance of (1−m) from feeder tap FT_{4,3}. For example, if m is 0.4 and the actual distance between feeder tap FT_{4,2} and feeder tap FT_{4,3} is 1000 feet (i.e., d=1000 feet), then the actual distance from feeder tap FT_{4,2} to fault node F is 400 (i.e., d·m) feet and the actual distance from fault node F to feeder tap FT_{4,3} is 600 (i.e., d·(m−1)) feet.

Fault node F has a fault impedance Z_{F} to ground where the fault impedance includes the fault resistance and the impedance of the connecting conductors between the fault node F and the fault ground.

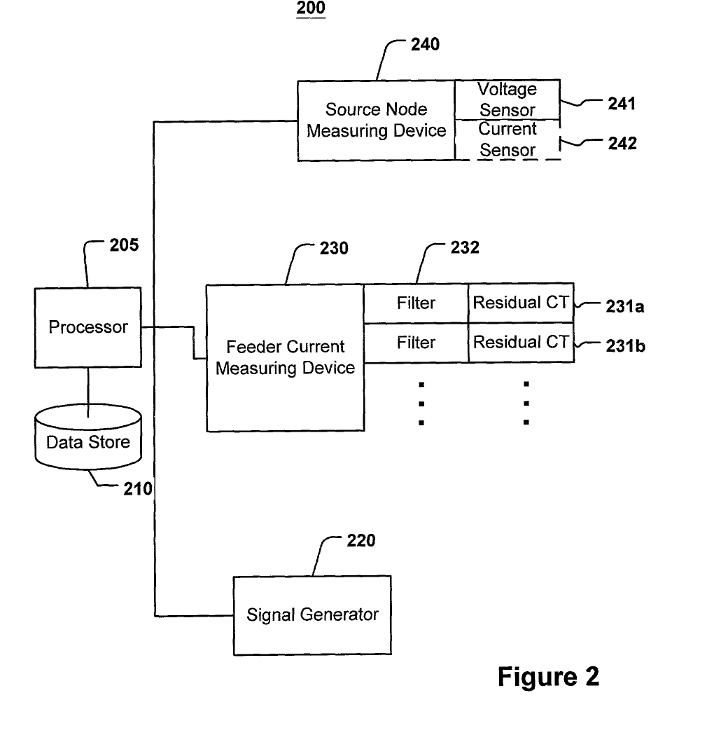

FIG. 2 is a block diagram of a system in accordance with one embodiment of the present invention. System 200 may be applied to power distribution system 10 of FIG. 1 to provide fault location as described in more detail below. As shown in FIG. 2, the system includes a processor 205, a data store 210, a signal generator 220, a feeder current measuring device 230, and a source node measuring device 240.

Processor 205 may be any processor suitable for performing calculations, receiving input data from measuring devices, and interfacing with a signal generator. For example, the processor 205 may be a protective relay with control capability, a control relay with control capability, a personal computer having data acquisition and control capability, an oscillographic data capture, or the like. In one embodiment, processor 205 is a personal computer executing a Labview™ program. For this embodiment, the fault location should be calculated within about eight power cycles from the fault; therefore, a program on a personal computer should be designed accordingly. Because the fault location is calculated upon detecting a fault, a fault location may be calculated for an intermittent fault. As such, the fault location may assist in locating an intermittent fault, which can be very difficult to locate otherwise.

Data store 210 stores predetermined power distribution system relative impedances and a power distribution system model (i.e., the interconnection of feeders FD, buses B, and segments). Data store 210 may store data received from the measuring devices 230, 240. Data store 210 may be a memory, a magnetic storage medium, an optical storage medium, a hard disk, a floppy disk, or the like.

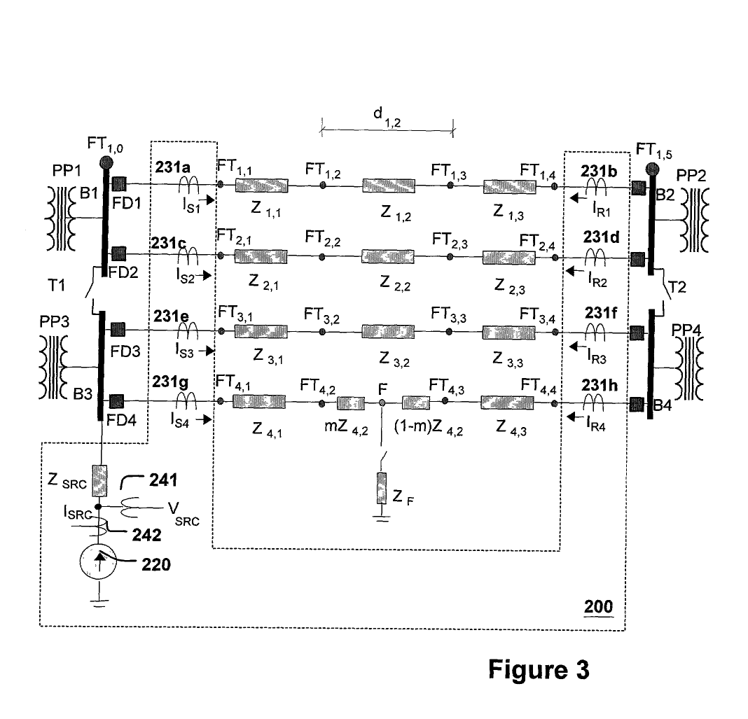

Signal generator 220 is coupled between ground and power distribution system 10, as best seen in FIG. 3. In one embodiment of the present invention, signal generator 220 is coupled to each phase of the power distribution system 10 by way of a transformer (not shown) such as a delta-wye transformer wherein the neutral center point of the ‘wye’ is coupled to ground.

Signal generator 220 may be any signal generator capable of interfacing with the voltage level of the power distribution system and injecting a controlled current or voltage signal at a measurement frequency between each phase of the power distribution system and ground (i.e., between a first phase and ground, between a second phase and ground, etc.).

Feeder current measuring device 230 includes a plurality of residual CTs 231 that output an analog signal substantially proportional to the residual current of a feeder. Residual current is the sum of the currents in all phases at a given point in a power distribution system. Typically, residual current is measured by placing a residual CT around all three phases of a three phase power distribution system.

Feeder current measuring device 230 includes at least two residual CT's. The number of residual CT's depends on the topology of the power distribution system.

In one embodiment of the present invention, as applied to power distribution system 10, feeder current measuring device 230 includes, for each feeder, two residual CTs. One residual CT senses the residual current from sending node S to a feeder (e.g., I_{S1}) and the other residual CT senses the residual current from receiving node R to a feeder (e.g., I_{R1}). As shown in FIG. 3, residual CT 231a senses residual current, I_{S1}, in feeder FD1 from sending node S and residual CT 231b senses the residual current, I_{R1}, in feeder FD1 from receiving node R. Feeder current measuring device 230 converts the analog signal of a residual CT to a digital signal using known analog to digital techniques before transmission to processor 205. Processor 205 uses the digital signals to determine a faulted feeder and to determine a fault location, as described in more detail below.

Residual CT 231 may include a frequency filter 232 for filtering frequencies from the analog output of the residual CT 231. Typically, filter 232 corresponds to the measurement frequency generated by signal generator 220. In one embodiment of the present invention, frequency filter 232 is a high pass filter that passes frequencies above 500 Hz. In this embodiment, 60 Hz line frequency of the power distribution system 10 is filtered out of the analog output of residual CT 231, for example, by using digital filtering based on a discrete Fourier transform to extract out the 600 Hz measurement component from the measured signals. In another embodiment of the present invention, frequency filter 232 is a bandpass filter that passes frequencies in a range around 600 Hz. Frequency filter 232 components may be any of several known filters, including an appropriate active or a passive RLC filter (not shown).

In another embodiment of the present invention, residual CT 231 outputs an analog signal to feeder current measuring device 230 for conversion to a digital signal, and then, feeder current measuring device 230 frequency filters the digital signal by any of several known digital signal processing techniques.

Source node measuring device 240 includes a voltage sensor 241 and optionally a current sensor 242 for measuring the voltage and current, respectively, of source node SRC. Source node SRC is defined herein as the node of the power distribution system that is connected to the signal generator. Current sensor 242 may output an analog signal and source node measuring device 240 may convert the analog signal to a digital signal using known analog to digital techniques before transmission to processor 205. Importantly, current sensor 242 is not required to estimate a fault location.

Voltage sensor 241 comprises a voltage sensor for each phase of power distribution system 10. Voltage sensor 241 may output an analog signal and source node measuring device 240 may convert the analog signal to a digital signal using known analog to digital techniques before transmission to processor 205. Processor 205 uses the digital signals to determine a fault and a faulted phase, as described in more detail below. Importantly, voltage sensor 241 is not used to calculate a fault location; rather, voltage sensor 241 is used to determine which phase is faulted. Also voltage sensor 241 may be used for calibration purposes.

In one embodiment of the present invention, processor 205 collects voltage and current data “simultaneously” by multiplexed channel scanning of the residual CTs 231. The number of data points sampled depends on the hardware speed and the number of channels physically set up in the hardware of processor 205. Processor 205 is configured to scan the line frequency and the measurement frequency at different sampling rates. Because the data is gathered “simultaneously”, Fourier transformation of the sampled data gives both the magnitudes and relative phase angles of the desired frequency components.

Fault Location for a Looped Power Distribution System

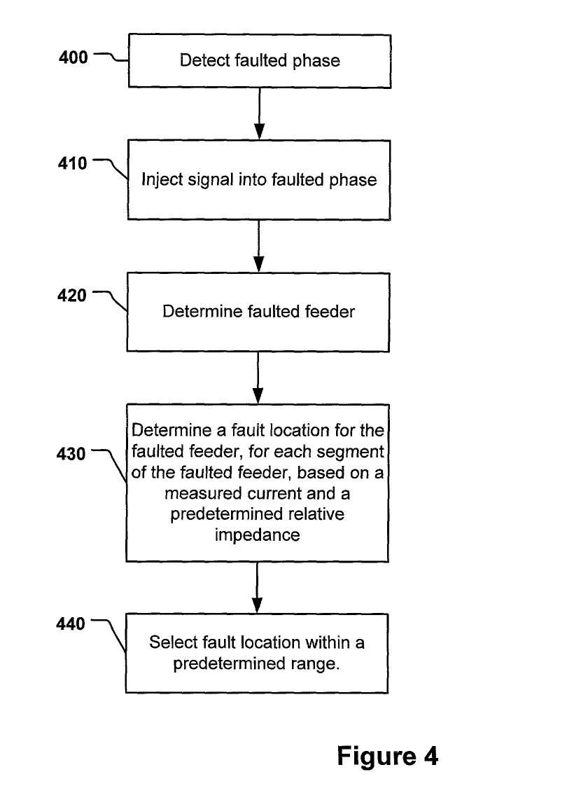

FIG. 4 is a flow chart of a method in accordance with one embodiment of the present invention and illustrating the operation of the system of FIG. 2 as applied to looped power distribution system 10 of FIG. 1. As shown in FIG. 4 at step 400, system 200 detects a faulted phase in power distribution system 10.

In the present embodiment, faults are detected by detecting a low phase-to-ground voltage at source node SRC. Specifically, source node measuring device 240 reads a voltage for each phase of the power distribution system 10 from voltage sensors 241 and compares each phase voltage to a predetermined voltage.

An ungrounded or high-impedance grounded power distribution system operating under ordinary conditions is nearly balanced. That is, the magnitude of the phase-to-phase voltages are substantially the same and the magnitude of the phase-to-ground voltages are substantially the same. An ordinary, phase-to-ground fault will result in a very small phase-to-ground voltage on the faulted phase. A single phase-to-ground fault will not effect the phase-to-phase voltages. Some power supply problems may also cause a relatively low phase to ground voltage on one of the phases and therefore may cause false fault detections. Therefore, in the present embodiment, relative voltages are used to minimize false fault detections that may result from various types of power supply problems such as phase imbalance or voltage sags.

First, the fault detection thresholds are determined from recent phase voltage readings. Phase-to-phase voltages are calculated based on measured phase-to-ground voltages. The minimum and maximum phase-to-phase voltages can then be determined by, for example:

|V_{MAX}|=max(|V_{AB}|, |V_{BC}|, |V_{AC}|) Equation 1

|V_{MIN}|=min(|V_{AB}|, V_{BC}|, V_{AC}|) Equation 2

where the thresholds are then defined as follows:

V_{MIN-Threshold}=V_{MIN-SETTING}×|V_{MIN}| Equation 3

V_{MAX-Threshold}=V_{MAX-SETTING}×|V_{MAX}| Equation 4

V_{INV-Threshold}=V_{INV-SETTING}×|V_{MAX}| Equation 5

In this embodiment, V_{MIN-SETTING}=10%; V_{MAX-SETTING}=85%; and V_{INV-SETTING}=105%, although the values may be varied. A fault is detected if the magnitude of any phase-to-ground voltage is less than V_{MIN-Threshold} and the phase-to-ground voltage on any other phase exceeds V_{MAX-Threshold}. In this case, the faulted phase is the phase with the voltage lower than V_{MIN-Threshold}.

Another type of fault is an inverted ground fault. An inverted ground fault may be caused by inductive faults and partially faulted motor windings, for example. A fault location cannot be determined for this type of fault; rather, these faults must be located manually. Therefore in this embodiment, if an inverted ground fault is detected, a fault location is not calculated. An inverted ground fault condition is detected when any phase-to-ground voltage is less than V_{MIN-threshold} and on any other phase the phase-to-ground voltage exceeds V_{INV-Threshold}.

Once a faulted phase is detected in step 400, at step 410, signal generator 220 injects a signal at a measurement frequency into the faulted phase. In the present embodiment, signal generator 220 injects 5 amperes at 600 Hz into the faulted phase for less than a second. Typically, the injected signal is small compared to the normal current of the power distribution system. Because the injected signal has a frequency different than the line frequency of power distribution system 10, the injected signal may be small and still be distinguished from the line frequency. In this manner, the injected signal may be distinguished from the normal line frequency of power distribution system 10.

In another embodiment of the present invention, signal generator 220 injects from about one ampere to about twenty amperes of current at a measurement frequency of about 100 Hz to about 10,000 Hz into the faulted phase of the power distribution system.

At step 420, processor 205 determines which feeder of power distribution system 10 is faulted by monitoring the injected signal as sensed and measured by residual CTs 231. Specifically, in the present embodiment, processor 205 receives, for each feeder, a sending current and a receiving current (e.g., I_{R1} and I_{S1}) of the feeder. Processor 205 sums the sending and receiving currents for each feeder to determine which feeder is faulted. If the sum of the current for a particular feeder is greater than a predefined current, then the particular feeder is determined to be faulted. The predefined current is selected to be larger than an expected sum of current for a particular feeder. The predefined current depends on the accuracy of the CT's used, the repeatability of the CT's, the matching of the CT's, the capacitance to ground, etc. Further, the centering of the conductors within the CT may affect the predefined current.

To further illustrate this technique, assume as shown in FIG. 1 that a fault occurs at fault node F on the second segment of feeder FD4 of power distribution system 10. For feeder FD1, processor 205 receives a current measurement from CT 231a and CT 231b, representing I_{S1} and I_{R1} respectively, and sums the current measurements. In this case, the current measurements sum to a value less than a predefined current because feeder FD1 is not faulted. Similarly, the current measurements for feeders FD2 and FD3 will sum to a value less than a predefined current at the measurement frequency. For feeder FD4, processor 205 receives a current measurement from CT 231g and CT 231h, representing I_{S4} and I_{R4} respectively, and sums the current measurements. In this case, the current measurements sum to a value greater than a predefined current because feeder FD4 is faulted.

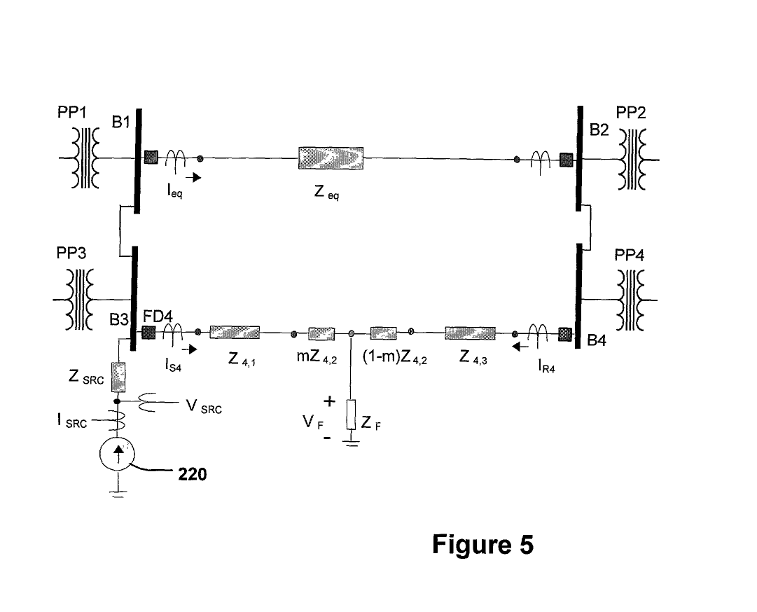

At step 430, processor 205 calculates a fault location for the faulted feeder segment based on a measured current and a predetermined relative impedance of the power distribution system. In greater detail, continuing with the exemplary power distribution system of FIG. 1, an equivalent electrical circuit for power distribution system 10 is modeled as shown in FIG. 5, where non-faulted feeders are represented by an equivalent impedance, Z_{eq}, and an equivalent feeder current, I_{eq}, according to:

$$\begin{matrix}{Z}_{eq} = [ \frac{1}{( {Z}_{1 , 1} + {Z}_{1 , 2} + {Z}_{1 , 3} )} + \frac{1}{( {Z}_{2 , 1} + {Z}_{2 , 2} + {Z}_{2 , 3} )} + \\ { \frac{1}{( {Z}_{3 , 1} + {Z}_{3 , 2} + {Z}_{3 , 3} )} ]}^{- 1}\end{matrix} \qquad Equation 6$$

and

I_{eq}=I_{S1}+I_{S2}+I_{S3} Equation 7

Alternatively, I_{eq} could be determined by using all feeder currents based on a simple estimation approach, where I_{eq}=(I_{S1}−I_{R1})/2+(I_{S2}−I_{R2})/2+(I_{S3}−I_{R3})/2, or by other techniques.

Assuming that the fault is located on the second segment of feeder FD4, two loop equations are written to relate source node voltage, V_{SRC}, and source node, I_{SRC}, current to fault voltage, V_{F}, as follows:

V_{F}=V_{SRC}−Z_{SRC}I_{SRC}−Z_{eq}I_{eq}−Z_{4,3}I_{R4}−(1−m)Z_{4,2}I_{R4} Equation 8

V_{F}=V_{SRC}−Z_{SRC}I_{SRC}−Z_{4,1}I_{S4}−mZ_{4,2}I_{S4} Equation 9

By subtracting Equation 9 from Equation 8, fault voltage V_{F}, source node voltage V_{SRC}, and source node current I_{SRC} are cancelled out as shown by:

0=−Z_{eq}I_{eq}−Z_{4,3}I_{R4}−(1−m)Z_{4,2}I_{R4}+Z_{4,1}I_{S4}+mZ_{4,2}I_{S4} Equation 10

Finally, solving for m (or m₂ in this case) results in:

$${m}_{2} = \frac{( {Z}_{4 , 2} + {Z}_{4 , 3} ) {I}_{R4} - {Z}_{4 , 1} {I}_{S4} + {Z}_{eq} {I}_{eq}}{{Z}_{4 , 2} ( {I}_{S4} + {I}_{R4} )} \qquad Equation 11$$

Similarly, fault locations may also be may be determined assuming that the fault node F is located on each other segment of the faulted feeder, in the manner described above. That is, a fault location m₁ may be determined assuming that the fault is located on the first segment of the faulted feeder and another fault location m₃ may be determined assuming that the fault is located on the third segment of the faulted feeder. However, only one fault location is ultimately selected as the correct fault location as described below in step 440.

As can be appreciated from Equation 11, the calculated fault location does not depend on actual impedances; rather, the calculated fault location depends only on relative impedances. For example, in Equation 11, M₂ depends on a first relative impedance of (Z_{4,2}+Z_{4,3})/Z_{4,2}, a second relative impedance of Z_{4,1}/Z_{4,2}, and a third relative impedance of Z_{eq}/Z_{4,2}. Because actual impedances may be difficult to measure accurately, the present invention may provide increased accuracy in fault location by using a relative impedance rather than an actual impedance.

To further explain relative impedances, if it is known that Z_{4,2} is twice as large as Z_{4,3}, that Z_{4,1} is three times as large as Z_{4,3} and Z_{eq} is one-third of Z_{4,3}, then the following values can be assigned,

Z_{4,3}=1

Z_{4,2}=2

Z_{4,1}=3

Z_{eq}=0.333

and the fault location technique works correctly regardless of the actual impedances.

At step 440 a fault location is selected from the fault locations calculated at step 430. To explain, m has a predetermined range selected to represent a relative distance of a feeder segment. In the present embodiment, the predetermined range is from zero to 1.0, which represent the distance between feeder tap FT_{4,2} and feeder tap FT_{4,3} when assuming that the fault lies between feeder tap FT_{4,2} and feeder tap FT_{4,3}. Similarly, the predetermined range for other segments is also from zero to 1.0. A calculated fault location outside of the predetermined range is not selected, as it lies at a point outside of the distance between the two nodes and a calculated fault location within the predetermined range is selected, as it lies at a point within the two nodes. For example, where the predetermined range of zero to 1.0 represents the distance between two nodes, if m₂ is calculated to be 2.4 in step 430, then the fault is located on another segment of the faulted feeder. This criterion is used to select a fault location from the fault locations calculated at step 430.

Determining Relative Impedances for a Looped Power Distribution System

In the embodiment of the present invention described above, the relative impedances are determined beforehand, for use in step 430 of FIG. 4. For example, test faults may be placed on the power system as described in more detail below. Some test faults may require opening a breaker to apply the test fault. It is desired to minimize the number of circuit breaker operations that are required to implement the test faults. A method of minimizing the number of test faults required is described below. To illustrate determining relative impedances with test faults in power distribution system 10, the possible positions for test faults are at feeder taps FT. Locations associated with transformer secondaries, such as FT_{1,0} and FT_{1,1} will most likely require deenergization of breakers. For other locations on the plant floor, such as FT_{1,2} and FT_{1,3} it may only be required to deenergize the equipment cabinet itself. Also, it should be appreciated that the relative impedances are determined at the measurement frequency, not the line frequency.

To begin, assign an impedance value to an impedance in the power distribution system. In this example, assign a value of one to the impedance Z_{4,1}+Z_{4,2}+Z_{4,3}, as seen in Equation 12:

Z_{4,1}+Z_{4,2}+Z_{4,3}=1 Equation 12

Then implement test faults at locations FT_{1,2}, FT_{1,3}, and FT_{1,5}. For each of the implemented test faults, loop equations are written. For a test fault at location FT_{1,2} two loop equations are:

V_{F}=V_{SRC}−Z_{SRC}I_{SRC}−Z_{1,1}I_{S1} Equation 13

and

V_{F}=V_{SRC}−Z_{SRC}I_{SRC}−(Z_{4,1}+Z_{4,2}+Z_{4,3})I_{S4}−Z_{1,3}I_{R1}−Z_{1,2}I_{R1} Equation 14

Subtracting the Equation 14 from Equation 13 yields:

Z_{1,1}I_{S1}−Z_{1,2}I_{R1}−Z_{1,3}I_{R1}=(1)I_{S4} (fault at FT_{1,2}) Equation 15

which is basically a loop equation involving feeders FD1 and FD4. Similarly, loop equations are written for test faults at the other two test fault locations for feeder FD1.

$$\begin{matrix}{Z}_{1 , 1} {I}_{S1} + {Z}_{1 , 2} {I}_{S1} - {Z}_{1 , 3} {I}_{R1} = ( 1 ) {I}_{S4} ( fault at {FT}_{1 , 3} ) & Equation 16 \\ {Z}_{1 , 1} {I}_{S1} + {Z}_{1 , 2} {I}_{S1} + {Z}_{1 , 3} {I}_{S1} = ( 1 ) {I}_{S4} ( fault at {FT}_{1 , 5} ) & Equation 17\end{matrix}$$

Equations 15-17 are solved simultaneously to determine Z_{1,1}, Z_{1,2}, and Z_{1,3}.

In the same manner, loop equations for feeders FD2 and FD3 are determined, for test faults at FT_{2,2}, FT_{2,3}, FT_{3,2}, FT_{3,3}, and FT_{1,5}.

For feeder FD2:

$$\begin{matrix}{Z}_{2 , 1} {I}_{S2} - {Z}_{2 , 2} {I}_{R2} - {Z}_{2 , 3} {I}_{R2} = ( 1 ) {I}_{S4} ( fault at {FT}_{2 , 2} ) & Equation 18 \\ {Z}_{2 , 1} {I}_{S2} + {Z}_{2 , 2} {I}_{S2} - {Z}_{2 , 3} {I}_{R2} = ( 1 ) {I}_{S4} ( fault at {FT}_{2 , 3} ) & Equation 19 \\ {Z}_{2 , 1} {I}_{S2} + {Z}_{2 , 2} {I}_{S2} + {Z}_{2 , 3} {I}_{S2} = ( 1 ) {I}_{S4} ( fault at {FT}_{1 , 5} ) & Equation 20\end{matrix}$$

For feeder FD3:

$$\begin{matrix}{Z}_{3 , 1} {I}_{S3} - {Z}_{3 , 2} {I}_{R3} - {Z}_{3 , 3} {I}_{R3} = ( 1 ) {I}_{S4} ( fault at {FT}_{3 , 2} ) & Equation 21 \\ {Z}_{3 , 1} {I}_{S3} + {Z}_{3 , 2} {I}_{S3} - {Z}_{3 , 3} {I}_{R3} = ( 1 ) {I}_{S4} ( fault at {FT}_{3 , 3} ) & Equation 22 \\ {Z}_{3 , 1} {I}_{S3} + {Z}_{3 , 2} {I}_{S3} + {Z}_{3 , 3} {I}_{S3} = ( 1 ) {I}_{S4} ( fault at {FT}_{1 , 5} ) & Equation 23\end{matrix}$$

Again, the loop equations are solved simultaneously for each feeder to determine the relative impedances.

Finally, to determine parameters for feeder FD4, test faults are placed at FT_{4,2}, FT_{4,3}, and FT_{1,5}. Using the impedances calculated above, the equivalent impedance Z_{eq}, and an equivalent feeder current I_{eq}, the equations for the test faults become:

$$\begin{matrix}{Z}_{4 , 1} {I}_{S4} - {Z}_{4 , 2} {I}_{R4} - {Z}_{4 , 3} {I}_{R4} = {Z}_{eq} {I}_{eq} ( fault at {FT}_{4 , 2} ) & Equation 24 \\ {Z}_{4 , 1} {I}_{S4} + {Z}_{4 , 2} {I}_{S4} - {Z}_{4 , 3} {I}_{R4} = {Z}_{eq} {I}_{eq} ( fault at {FT}_{4 , 3} ) & Equation 25 \\ {Z}_{4 , 1} {I}_{S4} + {Z}_{4 , 2} {I}_{S4} + {Z}_{4 , 3} {I}_{S4} = {Z}_{eq} {I}_{eq} ( fault at {FT}_{1 , 5} ) & Equation 26\end{matrix}$$

which are solved to determine the last three segment impedances.

In all, only nine test faults were required, since the test fault node FT_{1,5} data was used for more than one feeder. The above described method of determining relative impedances has a number of advantages. First, the impact of the fault impedance is cancelled out. This is important because contact resistance can vary from test to test. Second, voltages are not required, only residual CT measurements on the feeders. This is important because the voltage magnitudes may be too small to measure with sufficient accuracy. For example, if signal generator 220 injects 5 amperes of current, the measured voltage may be on the order of 50 mV. Finally, by using loop equations, it is possible to obtain the relative impedances with minimal breaker switching, which may significantly decrease the time required for obtaining predetermined values for the power distribution system. An additional advantage is that actual impedances may be obtained from the relative impedances by applying a common scaling factor (SF). The scaling factor is defined by:

Z_{t,j actual}=SF×Z_{t,J relative} Equation 27

where SF is a complex number.

Importantly, the present invention does not rely on voltage measurements to calculate a fault location. This is particularly important since the voltage levels at 600 Hz (a typical measurement frequency) are rather small, on the order of tens of millivolts.

Moreover, fault location is only dependent on relative impedances of the power distribution system, rather than actual impedances of the power distribution system. The actual impedances of power distribution system segments are a function of feeder construction and feeder length. The actual impedances of feeders might not be known ahead of time and the lengths can be difficult to accurately measure. Moreover, the actual impedances of the feeders at the measurement frequency of the signal generator are probably not known ahead of time. Further, measuring actual impedances may require that many segments of the power distribution system be removed from power. Fortunately, the present invention depends on relative impedances of segments of the power distribution system, which are simpler to determine than actual impedances.

Also importantly, the present invention is fast enough to determine a fault location for intermittent faults. Intermittent faults are very difficult to locate on ungrounded and high-impedance grounded power distributions systems. While ungrounded and high-impedance grounded power distributions systems can tolerate a single ground fault without tripping circuit breakers, a second ground fault may trip circuit breakers. Therefore, it is important to for an industrial power user to locate intermittent ground faults.

Fault Location and Determining Relative Impedances for a Radial Power Distribution System

In another embodiment of the present invention, a fault location may be determined for a radial power distribution system. FIG. 6 illustrates a radial power distribution system 600. As shown in FIG. 6, power distribution system 600 includes bus B5 connected to transformer PP5. Bus B5 is coupled to feeder FD5 which has one segment having an impedance Z_{5,1}.

FIG. 7 illustrates how the system of FIG. 2 can be applied to the power distribution system of FIG. 6, in accordance with this embodiment of the present invention. As shown in FIG. 7, signal generator 220 is connected to bus B5. Residual CT 231m senses the residual current in feeder FD5. A reference impedance Z_{REF} is connected to source node SRC and residual CT 231n senses the residual current in reference impedance Z_{REF}.

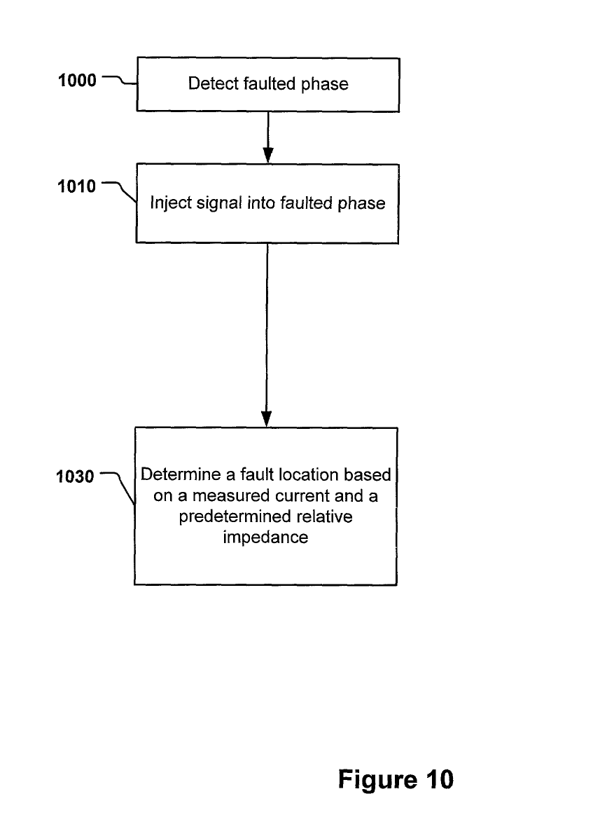

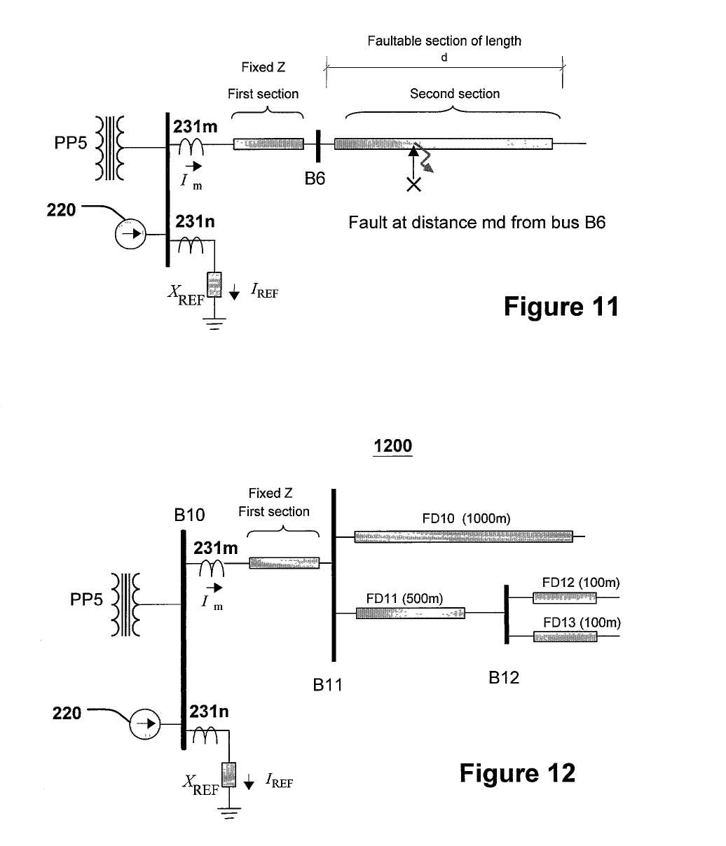

FIG. 10 is a flow chart illustrating the operation of the system of FIG. 2 as applied to the radial power distribution system 600 of FIG. 6, as well as illustrating a method for locating a fault in a radial power distribution system in accordance with this embodiment of the present invention.

As shown in FIG. 10 at step 1000, system 200 detects a faulted phase by detecting a low phase-to-ground voltage at the signal injector bus in the same manner as described above in connection with step 400 of the previous embodiment.

At step 1010, signal generator 220 injects a signal into the faulted phase as determined at step 1000. Also, reference impedance Z_{REF} is connected to bus B5 for the same duration that signal generator 220 is injecting a signal into the faulted phase.

At step 1030, processor 205 calculates a fault location based on the measured currents from residual CTs 231ₘ, 231ₙ and a predetermined relative impedance of power distribution system 600. The predetermined relative impedances for the system 600 can be determined using test faults in the same manner as described above for system 10, albeit using different circuit equations. An advantage of using relative impedances is that the residual CTs 231m, 231n can be identical in characteristics giving favorable comparison of current flow even with a distorted injected signal. Furthermore, the reference impedance Z_{REF} can be chosen so that the current divides approximately evenly for most faults, potentially improving measurement accuracy.

A prudent choice of reference impedance Z_{REF} can further aid in fault location. For example, the reference impedance Z_{REF} may be purely inductive. In this case, the ratio of the reference current I_{REF} to the fault current I_{F} (e.g., measured with CT 231m, as the fault current and Iₘ should be the same during a fault) that flows into the fault is obtained as follows, with reference to FIG. 8, which illustrates a fault at fault node F on the radial power distribution system 600:

V_{SRC}=(Z_{bus-to-fault}+Z_{F})I_{F}=jX_{REF}I_{REF} Equation 28

$$\frac{{I}_{REF}}{{I}_{F}} = \frac{( {Z}_{\text{bus-to-fault}} + {Z}_{F} )}{j {X}_{REF}} \qquad Equation 29$$

When fault impedance Z_{F} is resistive, the reactive part of the impedance of the segment portion (i.e., jX_{bus-to-fault}) is used to estimate the fault location according to:

$$\begin{matrix}\frac{{I}_{REF}}{{I}_{F}} = \frac{j {X}_{\text{bus-to-fault}}}{j {X}_{REF}} + \frac{{R}_{\text{bus-to-fault}} + {R}_{F}}{j {X}_{REF}} and , & Equation 30 \\ Re \{ \frac{{I}_{REF}}{{I}_{F}} \} = \frac{{X}_{\text{bus-to-fault}}}{{X}_{REF}} & Equation 31\end{matrix}$$

The parameters for fault location may be obtained by application of test faults as described below. For example, the parameter ratio can be rewritten as:

$$\begin{matrix}Re \{ \frac{{I}_{reference}}{{I}_{f}} \} = \frac{{X}_{\text{bus-to-fault}}}{{X}_{reference}} = \frac{{X}_{o}}{{X}_{reference}} + \\ \frac{{dx}_{c}}{{X}_{reference}} = {X}_{o , relative} + md {x}_{c , relative}\end{matrix} \qquad Equation 32$$

for a fault at test distance md, where m is the percentage of distance of the fault along the feeder segment, d is the length of the feeder segment, X₀ is a constant reactance term, x_{c} is a reactance per unit of distance, X_{o,relative} is the ratio of X₀ to X_{REF}, X_{c,relative} is the ratio of x_{c} to X_{REF}, and X_{REF} is the reactance of the reference impedance. Importantly, the actual value of the reference reactance and the actual value of the reactance per unit distance is unnecessary. However, if desired, the relative values my be scaled by a scale factor to obtain actual values according to:

x_{c}=SF×x_{c,relative} Equation 33

where SF is a scale factor.

Once X_{o,relative} and X_{c,relative} are determined by placing test faults on power distribution system 600, the fault may be located according to:

$$md = \frac{Re \{ \frac{{I}_{REF}}{{I}_{F}} \} - {X}_{o , relative}}{{x}_{c , relative}} \qquad Equation 34$$

where I_{REF} and I_{F} are measured by residual CTs 231m and 231n, respectively.

The fault location methodology described above assumes that the power system impedances—in relative or absolute terms—are known. The impedances may be determined in a number of ways, but the most accurate values will be determined using test faults and a least-square-error (LSE) estimation procedure. A matrix-based procedure of this type is described below for both radial and looped-systems.

Fault Location using a Characteristic Relative Impedance for a Radial Power Distribution System having One Radial Line

In an alternate embodiment of the present invention, a fault location is determined in step 1030 using a characteristic relative impedance rather than the relative impedance described above. In some cases, a segment of a power distribution system has non-uniform impedance with respect to the length of the segment. In this embodiment of the present invention, a characteristic relative impedance is determined by implementing test faults, measuring currents, and estimating a characteristic relative impedance by using a least-squared error criterion. The characteristic relative impedance is then used to determine a fault location.

On application of a single test fault at distance md from an end of a feeder segment:

Re{I_{ref}/Iₘ}≅mdx_{characteristic per unit of distance} Equation 35

where I_{ref} is the current measured in the reference impedance and Iₘ is measured fault current during the test fault. The characteristic reactance term, X_{characteristic per unit of distance} also includes reactance in the ground path to the fault. For simplicity of notation, Equation 35 may be rewritten as,

Re{[I_{ref}/Iₘ]}=[m]dx_{c}+[error] Equation 36

For a number of test faults at different distances md the data may be organized into a matrix format:

$$Re \{ [ \begin{matrix}{I}_{ref1} / {I}_{m1} \\ {I}_{ref2} / {I}_{m2} \\ ⋮ \\ {I}_{refN} / {I}_{mN}\end{matrix} ] \} = [ \begin{matrix}{m}_{f1} \\ {m}_{f2} \\ ⋮ \\ {m}_{f N}\end{matrix} ] {d}_{f} {x}_{c} + [ \begin{matrix}{e}_{1} \\ {e}_{2} \\ ⋮ \\ {e}_{N}\end{matrix} ] \qquad Equation 37$$

for test faults 1, 2, . . . N at test fault distances mf₁df, mf₂df, . . . m_{fN}df, respectively. The errors are assumed to have standard distribution and a zero norm. The least-squared error criterion solution to Equation 37 is given by:

x_{c}=(1/d)m⁽⁺⁾Re{I_{ref}/I_{m}} Equation 38

where the superscript (+) indicates pseudo-inverse operation. For a good least-squared error criterion fit of the data, test faults should be applied a number of times at each distance, and at as many distance points as is practicable. The parameter x_{c} is used to determine fault distances during actual faults since:

$${m}_{f} d ≅ \frac{Re \{ {I}_{ref} / {I}_{m} \}}{{x}_{c}} \qquad Equation 39$$

where I_{ref} and Iₘ are measured during the actual fault and the subscript f indicates the feeder in question. In this manner, a segment of a power distribution system may be modeled with a characteristic relative impedance and a fault location determined based on the characteristic relative impedance

Fault Location using a Characteristic Relative Impedance for a Radial Power Distribution System having One Radial Line Including a Fixed Impedance Segment and a Second Segment

In yet another embodiment of the present invention, a fault location is determined in step 1030 for a radial power distribution system is more accurately modeled by a first segment having a constant impedance and a second segment having a uniformly varying impedance, using a characteristic relative impedance. Both of the constant impedance and the uniformly varying impedance can be relative to a reference impedance. This embodiment has the advantage of including the signal generator, any fault application equipment, and any lead-in cable impedances in the model, and therefore may give more accurate results. In this embodiment, the linear relationship is given by:

Re{I_{ref}/Iₘ}=X_{o,relative}+md x_{c}+error Equation 40

or in matrix form:

$$Re \{ [ \begin{matrix}{I}_{ref1} / {I}_{m1} \\ {I}_{ref2} / {I}_{m2} \\ ⋮ \\ {I}_{refN} / {I}_{mN}\end{matrix} ] \} = [ \begin{matrix}1 & {m}_{f1} \\ 1 & {m}_{f2} \\ ⋮ & ⋮ \\ 1 & {m}_{fN}\end{matrix} ] [ \begin{matrix}{X}_{o , relative} \\ {x}_{c} {d}_{f}\end{matrix} ] + [ \begin{matrix}{e}_{1} \\ {e}_{2} \\ ⋮ \\ {e}_{N}\end{matrix} ] \qquad Equation 41$$

for a set of N test points along the feeder f. The least-squared error criterion solution is given by:

$$[ \begin{matrix}{X}_{o , relative} \\ {x}_{c} d\end{matrix} ] = {[ 1 \vert m ]}^{( + )} Re \{ {I}_{ref} / {I}_{m} \} \qquad Equation 42$$

where 1 is a column partition of 1's and m is the column partition of proportional test relative distances mf along the feeder f. A solution of X_{O} and x_{C}d for test faults at varying distances gives the linear and distance varying portion of the line reactance characteristic. The estimated distance to a fault, given X_{O} and x_{C} is:

$${m}_{f} {d}_{f} ≅ \frac{Re \{ {I}_{ref} / {I}_{m} \} - {X}_{o}}{{x}_{c}} \qquad Equation 43$$

where I_{ref} and Iₘ are measured during the actual fault.

Fault Location using a Characteristic Relative Impedance for a Radial Power Distribution System having Forked Radial Feeders

In still another embodiment of the present invention, a fault location is determined at step 1030 using a characteristic relative impedance which may be characterized by a reactance per-unit of distance on each feeder where the power distribution system is more accurately modeled by forked radial feeders.

FIG. 12 illustrates an exemplary forked radial power distribution system. As shown in FIG. 12, the power distribution system 1200 includes a bus B10 connected to bus B11 by a feeder segment with a fixed impedance of Z. Feeders FD10 and FD11 are connected to bus B11. Feeder FD10 has a length of 1000 meters and feeder FD11 has a length of 500 meters. Feeder FD11 is connected to bus B12, which in turn is connected to feeders FD12 and FD13, each having a length of 100 meters.

For a given fault, with distances measured from the source node SRC to the fault along the affected feeders, the measured currents are related by:

Re{I_{ref}/Iₘ}=X₀+{d₁m₁x_{c1}+d₂m₂x_{c2}+d₃m₃x_{c3}+. . . }+error Equation 44

In Equation 44, if the feeder is not in the path of the fault, the corresponding test distance is set to 0. If the feeder is in the path to the fault the distance will be either (a) the maximum distance of the connecting feeder segment if the fault is beyond a feeder fork or bus, or (b) the distance from the fork to the fault. Thus, for a fault 50 m from bus B12, m₁d₁=0 m; m₂d₂=500 m; m₃d₃=0 m; and m₄d₄=50 m. For multiple faults, the matrix equation becomes:

$$\begin{matrix}Re \{ [ \begin{matrix}{I}_{{ref}_{1}} / {I}_{m1} \\ {I}_{{ref}_{2}} / {I}_{m2} \\ ⋮ \\ {I}_{refN} / {I}_{mN}\end{matrix} ] \} = [ \begin{matrix}1 & {m}_{1 , 1} & {m}_{2 , 1} & ⋯ & {m}_{4 , 1} \\ 1 & {m}_{1 , 2} & {m}_{2 , 2} & & {m}_{4 , 2} \\ ⋮ & ⋮ & ⋮ & ⋰ & ⋮ \\ 1 & {m}_{1 , N} & {m}_{2 , N} & ⋯ & {m}_{4 , N}\end{matrix} ] \\ [ \begin{matrix}{X}_{o} \\ {d}_{1} {x}_{c1} \\ ⋮ \\ {d}_{4} {x}_{c4}\end{matrix} ] + [ \begin{matrix}{e}_{1} \\ {e}_{2} \\ ⋮ \\ {e}_{N}\end{matrix} ]\end{matrix} \qquad Equation 45$$

for a set of N test points, where the subscripts of m indicate first, the feeder segment involved and second, the test measurement taken.

The least-squared error criterion solution to Equation 45 gives the pertinent parameters for each feeder according to:

$$[ \begin{matrix}{X}_{o} \\ {d}_{1} {x}_{c1} \\ ⋮ \\ {d}_{4} {x}_{c4}\end{matrix} ] = {[ 1 \vert {m}_{Line1} \vert {m}_{Line2} … \vert {m}_{Line4} ]}^{( + )} Re \{ {I}_{ref} / {I}_{m} \} \qquad Equation 46$$

On occurrence of a fault, the distance to the fault may not be uniquely determined—any solution to Equation 47 with physically allowable combinations of mₓd values, all confined within their ranges (0≦mₓ≦100%) is a possibility.

Im{I_{ref}/Iₘ}=X₀+d₁m₁x_{c1}+d₂m₂x_{c2}+d₃m₃x_{c3}+. . . Equation 47

For example, when a fault occurs at the end of feeder FD13 in FIG. 12, the following solutions are possible assuming all feeder characteristics values x_{C} are identical:

m₁=0.6, m₂=0, m₃=0, and m₄=0;

m₁=0, m₂=1.0, m₃=1.0, and m₄=0;

m₁=0, m₂=1.0, m₃=0, and m₄=1.0.

In cases where a non-unique solution exists, it is desirable to narrow the search by fault indicators or other means.

As can be appreciated, the present invention provides a system and method of locating a fault on an ungrounded or high impedance grounded power system by using current measurements and predetermined relative impedances. The present invention can be applied to a looped power distribution system or a radial power distribution system. In addition, a characteristic relative impedance may be used to calculate a fault location in a variety of radial power distribution system configurations.

Fault Location of Looped Power Distribution System using a Least-square Error Criterion

In yet another embodiment of the present invention, a matrix-based least-squared error criterion is used to determine a fault location in a looped power distribution system. This embodiment uses more of the available residual current measurements, which may improve the accuracy of fault location, especially if one residual CT gives inaccurate measurements. However, some fault locations may be less accurate using this embodiment.

First, the power distribution system configuration and topology is modeled. Measurement current locations, measurement current directions, segment identities, segment current directions, and mesh current directions are assigned. A set of test faults is determined from the network topology. The minimum set of test faults includes faults at the junction of each feeder segment. The test faults are then implemented.

Second, the residual currents in each feeder is determined from the loop-current measurements taken for each test fault. This can be done in a simple manner by assigning the loop-currents measured in each feeder to currents in each segment. A more accurate method uses multiple measurements and performs a least-square error criterion estimate of the currents in each feeder segment. In either case, all feeder segment currents should be expressed in terms of measured currents for any test fault.

In matrix form, the matrix equation M Iₘ=S Iₑ is solved for each test fault where M and S are matrices, Iₘ is a vector of the measured currents, and Iₑ is a vector of the currents in each feeder segment. With the simple (no redundant measurement model, i.e., non-LSE model) model, matrix S is the identity matrix.

Third, the voltage drops around a closed circuit or mesh are summed to zero for all test faults. The voltage drops in each feeder segment are given by the current in each segment times the impedance in each segment. A reference impedance is used for relative comparison between impedances in the power distribution system.

In matrix form, the matrix equation C=Q Z is solved using a least- squared error criterion model for all test faults where Q is a matrix containing a definition of the reference impedance and all of the Iₑ currents for each test fault. C is a vector of constraints and Z is a vector of relative impedances to be determined.

For simplicity of formation of the matrices involved, the following is recommended.

All looped feeders are oriented horizontally in the circuit schematic.

Feeder segments are represented by two-terminal impedances oriented horizontally. The direction of element currents (currents in the feeder segments) is then assigned from left to right. Impedances and their currents are identified in a consistent order.

The directions of the measurement currents is assigned consistent with their physical mounting.

A set of mesh currents is assigned. A mesh is defined as the shortest closed circular path from one bus to itself through network impedances. For a completely looped system, Nₘₑₛₕₑₛ=N_{feeders}−N_{buses}+1. All mesh current directions are assigned clockwise.

A minimum number of test faults are applied at the junctions of segments (between impedance elements). Additional test faults may be applied at the bus side of the measurement CTs so that the feeder segment currents can always be determined from the measured currents. Note that faults on the buses may require some temporary de- energization of the bus, and hence may not be easy to apply.

Because a least-squared error criterion estimation procedure is used, any of these fault tests may be applied more than once.

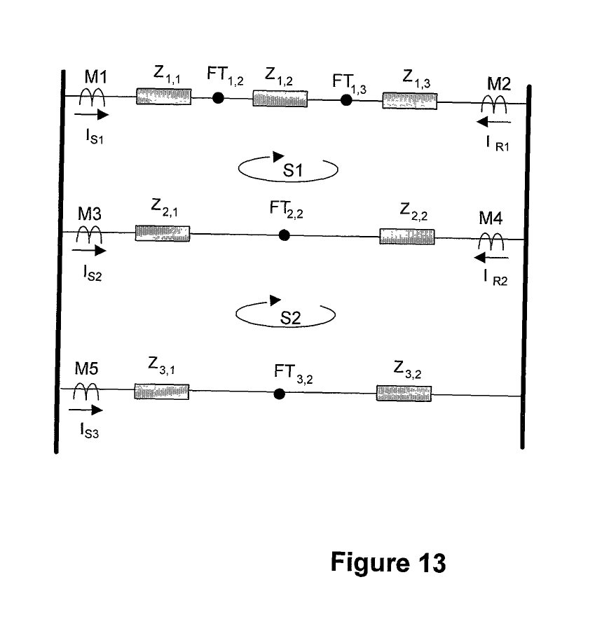

FIG. 13 illustrates an exemplary looped power distribution system diagrammed according to these topology rules. The same looped power distribution system is used below for numerical determination of the impedances in terms of a reference impedance. The numbers assigned correspond to the ordering of items used in the matrices and the missing feeder measurement will be used to illustrate a feature of the technique. These topology assignment rules can be applied to any planar network with the appropriate arrangement of the bus and feeder segment symbols.

In order to discuss this embodiment, the following nomenclature is used. Bold letters will be used for matrices and vectors. Subscript e is for the elements (feeder segments) and subscript m for the measurements. Superscript i indicates the i^{th} fault when i≧1.

M⁽ⁱ⁾=Metered current to current equation matrix for the i^{th} fault.

Iₘ⁽ⁱ⁾=Column vector of measured currents for the i^{th} fault.

S⁽ⁱ⁾=Segment current to current equation matrix for the i^{th} fault.

Iₑ⁽ⁱ⁾=Currents in each segment for the i^{th} fault.

C=Complete constraint column vector

C⁽ⁱ⁾=Constraint column vector for the i^{th} fault. This will also be the i^{th} partition of C.

Q=Complete mesh current incidence/impedance constraint matrix

Q⁽ⁱ⁾=Mesh current incidence/impedance constraint matrix for the i^{th} fault. This will also be the i^{th} partition of Q.

Z=Column vector of the impedances to be determined.

Each of the matrices has a specific size, and the numbers representing the column or row size are given below.

N_{E}=Number of elements (segments) in the network. Each element is identified by an impedance Z.

N_{F}=Number of fault tests used in determination of impedance parameters.

N_{M}=Number of feeder current measurement points

N_{Q}=Number of equations relating monitored currents and element currents

Nₛ=Number of mesh circuits

The matrices entries used for estimation of the currents in each feeder segment are discussed next. Since there are different sets of equations that can be used to relate the measured currents Iₘ to the currents in each element Iₑ, general procedure is described below for determination of currents Iₑ from the matrix equation M Iₘ=S Iₑ.

If a simple approach is used, the number of equations necessary is limited to the number of feeder segments (i.e. N_{Q}=N_{E}). In this case, the corresponding matrix S⁽ⁱ⁾ will be the identity matrix. This method assumes that the measurements are very accurate and that very little improvement can be obtained by measurement redundancy.

If a more redundant set of equations is used, matrix S⁽ⁱ⁾ will have multiple entries in each of its columns. For example, given a fault in the network above at point FT_{3,2}, the current in feeder segment Z_{1,1}, should be equal to measurement current I_{S1} (M1) and it should also be equal to the negative of the measurement current I_{R1} (M2). Ultimately, in the example cited, the least-squared error criterion estimate of the current in feeder segment E1 will be determined to be the average of currents I_{S1} and −I_{R1}.

The following steps are used to formulate the matrix M, which is used to relate element currents and measured currents.

1. Matrix M⁽ⁱ⁾ maps the metered currents to a set of equations. It is a matrix containing element entries of +1, −1, or 0 where each row has at least one non-zero entry. The matrix has a size of N_{Q}×N_{M} where N_{Q} is the number of equations and N_{M} is the number of measurements taken for the i^{th} fault.

The entries are given by:

M⁽ⁱ⁾(j, k)=1 if, for the j^{th} equation, the k^{th} monitored current passes through the element and the monitored current and element currents are in the same direction;

M⁽ⁱ⁾(j, k)=−1 if, for the the j^{th} equation, the k^{th} monitored current passes through the element and the monitored current and element currents are in opposite directions;

M⁽ⁱ⁾(j, k)=0 otherwise.

The equations for M⁽ⁱ⁾ (and equations for S⁽ⁱ⁾) are organized in such a manner that each element current, taken in turn, is described in terms of successive measurements. These are followed, as needed, by any remaining “pseudo-measurement(s)”. In the network shown, the current in the last feeder segment Z_{3,2} must be described in terms of the measurements I_{R1} and I_{R2} since there is no direct measurement of the current in Z_{3,2}. A Kirchoff's current law constraint was used assuming that very little of the fault current will find a path to ground from the connected bus through the 60 Hz network and beyond. No such equations can be used at the bus to which the signal generator is attached since the signal injection current is involved.

Matrices M⁽ⁱ⁾ and S⁽ⁱ⁾ must be formed using the exact same ordering criterion. The number of equations N_{Q} may vary according to fault point and network topology.

Note: In the example of FIG. 13

(1) Test faults are enumerated in the following order: FT_{1,2}, FT_{1,3}, FT_{2,2}, FT_{3,2}

(2) Impedances are enumerated in the following order: Z_{1,1}, Z_{1,2}, Z_{1,3}, Z_{2,1}, Z_{2,2}, Z_{3,1}, Z_{3,2}

(3) Measurements are enumerated in the following order: I_{S1}, I_{R1}, I_{S2}, I_{R2}, I_{S3} For the example network of FIG. 13, for a fault at point FT_{2,2}, the matrix M⁽³⁾ is an 11×5 matrix given below. The last row of the matrix is the calculated current in element Z_{3,1} Z_{3,2}, and simply adds redundancy to computation of estimated currents in elements Z_{3,1} and Z_{3,2}. Such an equation is not necessary for fault FT_{2,2}, but is required for a fault at FT_{3,2}.

$${M}^{( 3 )} = [ \begin{matrix}- 1 & 0 & 0 & 0 & 0 \\ 0 & 1 & 0 & 0 & 0 \\ - 1 & 0 & 0 & 0 & 0 \\ 0 & 1 & 0 & 0 & 0 \\ - 1 & 0 & 0 & 0 & 0 \\ 0 & 1 & 0 & 0 & 0 \\ 0 & 0 & - 1 & 0 & 0 \\ 0 & 0 & 0 & 1 & 0 \\ 0 & 0 & 0 & 0 & - 1 \\ 0 & 0 & 0 & 0 & - 1 \\ 0 & - 1 & 0 & - 1 & 0\end{matrix} ]$$

2. Column vector Iₘ⁽ⁱ⁾ is the measured currents for the i^{th} fault. As such, it is an ordered list of the measurements obtained for this fault.

The entries are given by:

Iₘ⁽ⁱ⁾(j,1)=the j^{th} measurement current.

3. Matrix S⁽ⁱ⁾ maps the element currents to a set of equations. It is a matrix containing element entries of +1 or 0 where each row has a single non-zero entry. The matrix has a size of N_{Q}×N_{E} where N_{Q} is the number of equations and N_{E} is the number of elements (segments) for the i^{th} fault.

The entries are given by:

S⁽ⁱ⁾(j, k)=1 if, for the j^{th} equation, the kth current passes through the element;

S⁽ⁱ⁾(j, k)=0 otherwise.

As above, the equations for S⁽ⁱ⁾ are organized in such a manner that each element current, taken in turn, is described in terms of successive measurements. These are followed, as needed, by any remaining “pseudo-measurement(s)”. In the network shown above, for a fault at FT_{2,2}, the matrix S⁽³⁾ is given by:

$${S}^{( 3 )} = [ \begin{matrix}1 & 0 & 0 & 0 & 0 & 0 & 0 \\ 1 & 0 & 0 & 0 & 0 & 0 & 0 \\ 0 & 1 & 0 & 0 & 0 & 0 & 0 \\ 0 & 1 & 0 & 0 & 0 & 0 & 0 \\ 0 & 0 & 1 & 0 & 0 & 0 & 0 \\ 0 & 0 & 1 & 0 & 0 & 0 & 0 \\ 0 & 0 & 0 & 1 & 0 & 0 & 0 \\ 0 & 0 & 0 & 0 & 1 & 0 & 0 \\ 0 & 0 & 0 & 0 & 0 & 1 & 0 \\ 0 & 0 & 0 & 0 & 0 & 0 & 1 \\ 0 & 0 & 0 & 0 & 0 & 0 & 1\end{matrix} ]$$

4. Column vector Iₑ⁽ⁱ⁾ is the estimates of the element currents.

The entries are given by:

Iₑ⁽ⁱ⁾(j,1)=the j^{th} element (feeder segment) current.

Iₑ₍ᵢ₎ is given by solution of the matrix equation M⁽ⁱ⁾ Iₘ⁽ⁱ⁾=S⁽ⁱ⁾Iₑ⁽ⁱ⁾ for each fault (i).

A least-squared-error criterion solution for the currents in each element is given by:

Iₑ⁽¹⁾=(S⁽ⁱ⁾)⁽⁺⁾M⁽¹⁾Iₘ⁽¹⁾

Where the superscript (+) indicates the pseudo-inverse operation.

The matrices entries used for determination of the impedances of each feeder segment are discussed next. Once the feeder segment currents Iₑ⁽ⁱ⁾ are known for each fault (i), the procedure described below is used to determine Z from the matrix equation C=Q Z. Note that matrices C and Q consist of partitions involving two different components—one is the definition of the reference impedance in terms of the impedances Z, and the second is the mesh current constraints involving the fault currents Iₑ.

The following steps are used to formulate the matrices Q and C, which are used to estimate impedances from estimated element currents.

1. Column vector C⁽ⁱ⁾ contains the impedance constraints and the mesh circuit voltage drop information.

(a) A 1×1 vector C⁽⁰⁾ is defined as the reference impedance. This reference impedance may be assigned an actual value, or may be set to 1.0.

(b) An Nₛ×1 vector C⁽ⁱ⁾ (1≦i≦N_{F}) is defined as the voltage drop in a mesh circuit. Since there are no 600 Hz voltage sources in the feeder network, all elements of this vector are set to 0.

2. Matrix Q⁽ⁱ⁾ contains the impedance constraints and the mesh current incidence.

(a) A 1×N_{E} row vector Q⁽⁰⁾ is determined such that C⁽⁰⁾=Q⁽⁰⁾Z. This equation assures that reference impedance is defined in terms of the N_{E} undetermined impedances in the network.

In the power distribution system of FIG. 13, a reference impedance was defined in terms of the sum of the two segment impedances Z_{1,2} and Z_{1,3}. Q⁽⁰⁾ is therefore given by:

Q⁽⁰⁾[0110000]

And the corresponding partition of C,

C⁽⁰⁾=[1]

(b) An N_{S}×N_{E} matrix Q⁽ⁱ⁾ Q⁽ⁱ⁾ (1≦i≦N_{F}) is a matrix of estimated element (segment) currents which are used to determine the total voltage drop in a mesh circuit.

The entries of Q⁽ⁱ⁾ (1≦i≦N_{F}) are given by:

Q⁽ⁱ⁾(j, k)=Iₑ⁽ⁱ⁾(j, 1) if mesh current j passes through element k and element and loop currents are in the same direction;

Q⁽ⁱ⁾(j, k)=−Iₑ⁽ⁱ⁾(j, 1) if mesh current j passes through element k and element and loop currents are in the opposite direction;

Q⁽ⁱ⁾(j, k)=0 otherwise.

Thus, for a fault at FT_{2,2}, the matrix Q⁽³⁾ is:

$${Q}^{( 3 )} = [ \begin{matrix}- 0.4444 & - 0.4444 & - 0.4444 & 1.6667 & - 1.1111 & 0 & 0 \\ 1 & 0 & 0 & - 1.6667 & 1.1111 & 0.6667 & 0.6667\end{matrix} ]$$

Given that the currents in elements Z_{1,1}, Z_{1,2} and Z_{1,3}=−0.4444; the current in Z_{2,1}=−1.6667; the current in Z_{2,2}1.1111; and the currents in Z_{3,1} and Z_{3,2} are −0.6667.

3. Matrix Z is an N_{E}×1 column vector containing the network impedances (or the relative network impedances) to be estimated.

4. To determine the unknown impedances:

(a) Construct the complete C and Q matrices from the matrix partitions:

$$C = [ \begin{matrix}{C}^{( 0 )} \\ {C}^{( 1 )} \\ ⋮ \\ {C}^{( {N}_{F} )}\end{matrix} ] ; Q = [ \begin{matrix}{Q}^{( 0 )} \\ {Q}^{( 1 )} \\ ⋮ \\ {Q}^{( {N}_{F} )}\end{matrix} ] ;$$

(b) This is an over-determined description of the constraints and test data. The least-squared-error criterion estimate of the impedance elements is given by:

Z=(Q)⁽⁺⁾C

where the superscript (+) again indicates the pseudo-inverse operation.

Results of this procedure for the sample network of FIG. 13 are described below.

The original network data was: Z^{T}ₜᵣᵤₑ=[0.5 0.2 0.8 0.6 0.3 0.8 0.2].

The reference impedance of Z(2,1)+Z(3,1) was chosen so that comparison of the results from parameter estimates did not require scaling. Use of the procedure with fault data to four significant figures gives estimates and relative parameter errors of:

Z^{T}ₑₛₜ=[0.5000 0.2000 0.8000 0.5999 0.3000 0.7999 0.1999].

e^{T}_{in-%}=[−0.0029 −0.0139 0.0035 −0.0089 −0.0000 −0.0095 −0.0308]

When the fault test measurement data is corrupted by rounding to the nearest 0.05, the estimation procedure still gives useable results:

Z^{T}ₑₛₜ=[0.5149 0.1913 0.8086 0.6262 0.3165 0.8359 0.2236].

e^{T}_{in-%}=[2.9864 −4.3625 1.0809 4.3732 5.4891 4.4828 11.8203]

Only two of the errors are larger than 5% in magnitude.

As can be appreciated, the above described system and method meet the aforementioned need for a system and method for calculating a fault location in an ungrounded or high-impedance grounded power distribution system without relying on voltage measurements and without relying on actual impedance values.

Although not required, the present invention may be embodied in the form of program code (i.e., instructions) stored on a computer-readable medium, such as a magnetic, electrical, or optical storage medium, including without limitation a floppy diskette, CD-ROM, CD-RW, DVD-ROM, DVD-RAM, magnetic tape, flash memory, hard disk drive, or any other machine-readable storage medium, wherein, when the program code is loaded into and executed by a machine, such as a computer, the machine becomes an apparatus for practicing the invention. The present invention may also be embodied in the form of program code that is transmitted over some transmission medium, such as over electrical wiring or cabling, through fiber optics, over a network, including the Internet or an intranet, or via any other form of transmission, wherein, when the program code is received and loaded into and executed by a machine, such as a computer, the machine becomes an apparatus for practicing the invention. When implemented on a general-purpose processor, the program code combines with the processor to provide a unique apparatus that operates analogously to specific logic circuits.

It is to be understood that the foregoing description has been provided merely for the purpose of explanation and are in no way to be construed as limiting of the present invention. Where the invention has been described with reference to embodiments, it is understood that the words which have been used herein are words of description and illustration, rather than words of limitation. Further, although the invention has been described herein with reference to particular structure, materials and/or embodiments, the invention is not intended to be limited to the particulars disclosed herein. Rather, the invention extends to all functionally equivalent structures, methods and uses, such as are within the scope of the appended claims. Those skilled in the art, having the benefit of the teachings of this specification, may effect numerous modifications thereto and changes may be made without departing from the scope and spirit of the invention in its aspects.

What is claimed is:

1. A method for locating a fault in a power distribution system having a line frequency, the power distribution system including a plurality of phases, the power distribution system including at least one feeder, each of the at least one feeder including at least one segment, the method comprising:
detecting a faulted phase from the plurality of phases of the power distribution system;
injecting a measurement signal having a measurement frequency into the detected faulted phase, the measurement frequency being a different frequency than the line frequency; and
determining a fault location for a selected segment based on at least one measured residual current corresponding to the injected signal and a predetermined relative impedance of the power distribution system.

2. The method of claim 1 further comprising placing test faults on the power distribution system to determine a relative impedance of the power distribution system.

3. The method of claim 1 wherein the detecting a faulted phase further comprises detecting a faulted phase based on detecting a relative low phase-to-ground voltage.

4. The method of claim 1 wherein the detecting a faulted phase further comprises:
measuring a first phase-to-ground voltage for a first phase of the plurality of phases;
measuring a second phase-to-ground voltage for a second phase of the plurality of phases; and
determining a faulted phase as the first phase if the first phase-to-ground voltage is less than a predetermined minimum voltage and the second phase-to-ground voltage is greater than a predetermined maximum voltage.

5. The method of claim 4 wherein the predetermined minimum voltage V_{MIN-Threshold} is determined by:
V_{MIN-Threshold}=V_{MIN-SETTING}×|V_{MIN}|

where V_{MIN-SETTING} is about 0.1,

|V_{MIN}|=min(|V_{AB}|, |V_{BC}|, |V_{AC}|),
where V_{AB} is a measured voltage from phase A to phase B.
V_{BC} is a measured voltage from phase B to phase C, and
V_{AC} is a measured voltage from phase A to phase C.

6. The method of claim 4 wherein the predetermined maximum voltage V_{MAX-Threshold} is determined by:
V_{MAX-Threshold}=V_{MAX-SETTING}×|V_{MAX}|

where V_{MAX-SETTING} is about 0.85,

|V_{MAX}|=max(|V_{AB}|, |V_{BC}|, |V_{AC}|),
where V_{AB} is a measured voltage from phase A to phase B,
V_{BC} is a measured voltage from phase B to phase C, and
V_{AC} is a measured voltage from phase A to phase C.

7. The method of claim 1 wherein the injecting a measurement signal further comprises injecting from about one ampere to about twenty amperes of current at a measurement frequency between about 100 Hz and about 10,000 Hz into the faulted phase of the power distribution system.

8. The method of claim 1 wherein the injecting a measurement signal further comprises injecting an about five ampere current signal at a measurement frequency of about 600 Hz for less than a second into the faulted phase of the power distribution system.

9. The method of claim 1 wherein the power distribution system is a looped power distribution system and each feeder includes a sending node and a receiving node, the method further comprising:
determining a faulted feeder from the at least one feeder based on the injected measurement signal; and
selecting the determined fault location if the determined fault location is within a predetermined range.

10. The method of claim 9 wherein the determining a faulted feeder further comprises:
measuring, for a selected feeder of the at least one feeder, a first residual current from the sending node to the selected feeder and a second residual current from the receiving node to the selected feeder;
summing the first residual current and the second residual current; and
determining the selected feeder as the faulted feeder if the summed residual currents are greater than a predetermined current.

11. The method of claim 9 wherein measuring a first residual current and measuring a second residual current further comprises filtering the first and second residual current at a frequency corresponding to the measurement frequency.

12. The method of claim 9 wherein determining a fault location for the selected segment of the faulted feeder further comprises:
modeling feeders of the at least one feeder that are not determined as a faulted feeder as an equivalent feeder at the measurement frequency;
modeling the selected segment as having a first impedance of m*Z and a second impedance of (1−m)*Z, where m is the relative distance of the fault location on the selected segment, and Z is the impedance of the selected segment;
modeling the power distribution system with at least one loop equation for the modeled equivalent feeder and the modeled selected segment; and
determining a fault location based on the at least one loop equation and the relative distance.

13. The method of claim 9 wherein selecting the determined fault location further comprises selecting the determined fault location based on a predetermined range representing a full distance of the selected segment.

14. The method of claim 13 wherein the predetermined range is from zero to one.

15. The method of claim 1 wherein the power distribution system is a radial power distribution system, each feeder includes one segment, and each feeder includes a sending node, the method further comprising:
connecting a reference impedance from the sending node to ground upon injecting the measurement signal.

16. The method of claim 15 wherein determining a fault location further comprises:
measuring a current in the reference impedance;
measuring a fault current; and
determining a fault location according to:
$$md = \frac{Re \{ \frac{{I}_{REF}}{{I}_{F}} \} - {X}_{o , relative}}{{x}_{c , relative}}$$
where d is the length of a faulted feeder segment,
m is location of the fault given in percentage of distance along the faulted feeder segment,
I_{REF} is the measured current in the reference impedance,
I_{F} is the measured fault current,
Re{I_{REF}/I_{F}} is the real part of the ratio of I_{REF} to I_{F},
X_{O} is a constant reactance term,
x_{C} is a reactance per unit of distance,
X_{o,relative} is the ratio of X_{O} to X_{REF},
X_{c,relative} is the ratio of x_{c} to X_{REF}, and
X_{REF} is the reactance of the reference impedance.

17. The method of claim 15 further comprising:
modeling one of the at least one feeder as having a characteristic relative impedance per unit of length.

18. The method of claim 17 wherein modeling further comprises modeling one of the at least one feeder as having a characteristic relative impedance per unit of length according to:
x_{c}=(1/d)m⁽⁺⁾Re{I_{ref}/Iₘ}
where x_{c} is the characteristic relative impedance per unit of length,
d is a distance of a feeder segment having a test fault,
m is a matrix of relative distances of test faults on feeder segments,
the superscript (+) indicates a pseudo-inverse operation,
I_{ref} is a matrix of reference currents measured during a test fault,
Iₘ is a matrix of fault currents measured during a test fault, and
x_{c} is determined according to a least-square error criterion.

19. The method of claim 18 further comprising determining a fault location according to:
$${m}_{f} d ≅ \frac{Re \{ {I}_{ref} / {I}_{m} \}}{{x}_{c}}$$
where
d is a distance of a feeder segment having a fault,
mf is a relative distance of the fault on the faulted feeder segment,
I_{ref} is a reference current measured during the fault,
Iₘ is a fault current measured during a the fault, and
x_{c} is a characteristic relative impedance per unit of length.

20. The method of claim 15 further comprising
modeling one of the at least one feeder as including a first segment and a second segment, the first segment having a characteristic relative impedance and the second segment having a characteristic relative impedance per unit of length.

21. The method of claim 20 wherein modeling further comprises modeling one of the at least one feeder according to:
$$[ \begin{matrix}{X}_{o , relative} \\ {x}_{c} d\end{matrix} ] = {[ 1 \vert m ]}^{( + )} Re \{ {I}_{ref} / {I}_{m} \}$$
where m is a matrix of relative distances of test faults on feeder segments,
the superscript (+) indicates a pseudo-inverse operation,
I_{ref} is a matrix of reference currents measured during a test fault,
Iₘ is a matrix of fault currents measured during a test fault,
X_{o,relative} is the characteristic relative impedance of the first segment,
x_{c} is the characteristic relative impedance per unit of length of the second segment,
d is a distance of a feeder segment,
and x_{c} and X_{o,relative} are determined according to a least-square error criterion.

22. The method of claim 21 further comprising determining a fault location according to:
$${m}_{f} d ≅ \frac{Re \{ {I}_{ref} / {I}_{m} \} - {X}_{o}}{{x}_{c}}$$
where
d is a distance of a feeder segment having a fault,
mf is a relative distance of the fault on the faulted feeder segment,
I_{ref} is a reference current measured during the fault,
Iₘ is a fault current measured during a the fault,
x_{c} is a characteristic relative impedance per unit of length of the second segment, and
X₀ is a characteristic relative impedance of the first segment.

23. The method of claim 15 wherein the power distribution system includes forked feeders, the method further comprising:
modeling one of the at least one feeder as having a characteristic relative impedance and the other feeders as having a characteristic relative impedance per unit of length.

24. The method of claim 23 wherein modeling further comprises modeling one of the at least one feeder as having a characteristic relative impedance and the other feeders as having a characteristic relative impedance per unit of length according to:
$$[ \begin{matrix}{X}_{o} \\ {d}_{1} {x}_{c1} \\ ⋮ \\ {d}_{4} {x}_{c4}\end{matrix} ] = {[ 1 \vert {m}_{Line1} \vert {m}_{Line2 } … \vert {m}_{Line4} ]}^{( + )} Re \{ {I}_{ref} / {I}_{m} \}$$
Xₒ is the characteristic relative impedance of the first feeder.
where x_{cq} is the characteristic relative impedance per unit of length of the q-th feeder,
d_{q} is the distance of the q-th feeder,
m is a matrix of relative distances of test faults,
the superscript (+) indicates a pseudo-inverse operation,
I_{ref} is a matrix of reference currents measured during a test fault,
Iₘ is a matrix of fault currents measured during a test fault,
and x_{cq} and Xₒ are determined according to a least-square error criterion.

25. The method of claim 1 further comprising:
modeling the power distribution system with a loop equation for each of the at least one feeder; and
determining a fault location by using a least-squared error criterion.

26. A system for locating a fault in a power distribution system having a line frequency, the power distribution system including a plurality of phases, the power distribution system including at least one feeder, each feeder including at least one segment, the system comprising:
a processor for determining a fault location in the power distribution system;
a signal generator for injecting a signal at a measurement frequency into a source node of the power distribution system, the signal generator coupled to the processor for the processor to command the signal generator to inject the signal;
a source node measuring device comprising a voltage sensor for each of the plurality of phases, the source node measuring device coupled to the processor for measuring a voltage of each phase; and
a feeder current measuring device comprising a plurality of residual current transformers for measuring a residual current in a feeder;
wherein the processor detects a faulted phase from the plurality of phases of the power distribution system, the signal injector injects a measurement signal having a measurement frequency into the detected faulted phase, the measurement frequency being a different frequency than the line frequency, and the processor determines a fault location for a selected segment based on at least one measured residual current corresponding to the injected signal and a predetermined relative impedance of the power distribution system.

27. The system of claim 26 further comprising a data store for storing the predetermined relative impedance.

28. The system of claim 26 wherein the processor further detects a faulted phase based on detecting a relative low phase-to-ground voltage.

29. The system of claim 26 wherein the processor further receives a measured first phase-to-ground voltage for a first phase of the plurality of phases from the source node measuring device, receives a measured second phase-to-ground voltage for a second phase of the plurality of phases from the source node measuring device, and determines a faulted phase as the first phase if the first phase-to-ground voltage is less than a predetermined minimum voltage and the second phase-to-ground voltage is greater than a predetermined maximum voltage.

30. The system of claim 29 wherein the processor determines the predetermined minimum voltage V_{MIN-Threshold} by:
V_{MIN-Threshold}=V_{MIN-SETTING}×|V_{MIN}|

where V_{MIN-SETTING} is about 0.1,

|V_{MIN}|=min(|V_{AB}|, |V_{BC}|, |V_{AC}|),
where V_{AB} is a measured voltage from phase A to phase B,
V_{BC} is a measured voltage from phase B to phase C, and
V_{AC} is a measured voltage from phase A to phase C.

31. The system of claim 29 wherein the processor determines the predetermined maximum voltage V_{MAX-threshold} by:
V_{MAX-Threshold}=V_{MAX-SETTING}×|V_{MAX}|

where V_{MAX-SETTING} is about 0.85,

|V_{MAX}=max(|V_{AB}|, |V_{BC}|, |V_{AC}|),
where V_{AB} is a measured voltage from phase A to phase B,
V_{BC} is a measured voltage from phase B to phase C, and
V_{AC} is a measured voltage from phase A to phase C.

32. The system of claim 26 wherein the signal generator injects a measurement signal from about one ampere to about twenty amperes of current at a measurement frequency of between about 100 Hz and about 10,000 Hz into the faulted phase of the power distribution system.

33. The system of claim 26 wherein the signal generator injects a measurement signal of about five ampere current signal at a measurement frequency of about 600 Hz for less than a second into the faulted phase of the power distribution system.

34. The system of claim 26 wherein the power distribution system is a looped power distribution system and each feeder includes a sending node and a receiving node, and the processor further determines a faulted feeder from the at least one feeder based on the injected measurement signal, and selects the determined fault location if the determined fault location is within a predetermined range.

35. The system of claim 34 wherein the processor further receives from the current measuring device, for a selected feeder, a first measured residual current representing a residual current from the sending node to the selected feeder and a second measured residual current representing a residual current from the receiving node to the selected feeder, sums the first measured residual current and the second measured residual current; and determines the selected feeder as the faulted feeder if the summed residual currents are greater than a predetermined current.

36. The system of claim 34 wherein the current measuring device further comprises a frequency filter for each of the plurality of residual current transformers, the filter corresponding to the measurement frequency.

37. The system of claim 34 wherein the processor further models feeders of the at least one feeder that are not determined as a faulted feeder as an equivalent feeder at the measurement frequency, models the selected segment as having a first impedance of m*Z and a second impedance of (1−m)*Z, where m is the relative distance of the fault location on the selected segment, and Z is the impedance of the selected segment, models the power distribution system with at least one loop equation for the modeled equivalent feeder and the modeled selected segment, and determines a fault location based on the at least one loop equation and the relative distance.

38. The system of claim 34 wherein the processor further selects the determined fault location based on a predetermined range representing a full distance of the selected segment.

39. The system of claim 38 wherein the predetermined range is from zero to one.

40. The system of claim 26 wherein the power distribution system is a radial power distribution system, each feeder includes one segment, and each feeder includes a sending node, and the processor farther commands the connection of a reference impedance from the sending node to ground upon commanding the signal generator to inject a measurement signal.

41. The system of claim 40 wherein the processor further receives from the feeder current measuring device, a measured current in the reference impedance, receives from the feeder current measuring device, a measured a fault current, and determines a fault location according to:
$$md = \frac{Re \{ \frac{{I}_{REF}}{{I}_{F}} \} - {X}_{o , relative}}{{x}_{c , relative}}$$
where d is the length of a faulted feeder segment,
m is location of the fault given in percentage of distance along the faulted feeder segment,
I_{REF} is the measured current in the reference impedance,
I_{F} is the measured fault current,
Re{I_{REF}/I_{F}} is the real part of the ratio of I_{REF} to I_{F},
X₀ is a constant reactance term,
x_{c} is a reactance per unit of distance,
X_{o,relative} is the ratio of X₀ to X_{REF},
X_{c,relative} is the ratio of x_{c} to X_{REF}, and
X_{REF} is the reactance of the reference impedance.

42. The system of claim 40 wherein the processor further models one of the at least one feeder as having a characteristic relative impedance per unit of length.

43. The system of claim 42 wherein the processor further models one of the at least one feeder as having a characteristic relative impedance per unit of length according to:
x_{c}=(1/d)m⁽⁺⁾Re{I_{ref}/Iₘ}
where x_{c} is the characteristic relative impedance per unit of length,
d is a distance of a feeder segment having a test fault,
m is a matrix of relative distances of test faults on feeder segments,
the superscript (+) indicates a pseudo-inverse operation,
I_{ref} is a matrix of reference currents measured during a test fault,
Iₘ is a matrix of fault currents measured during a test fault, and
x_{c} is determined according to a least-square error criterion.

44. The system of claim 43 wherein the processor further determines a fault location according to:
$${m}_{f} d ≅ \frac{Re \{ {I}_{ref} / {I}_{m} \}}{{x}_{c}}$$
where
d is a distance of a feeder segment having a fault,
mf is a relative distance of the fault on the faulted feeder segment,
I_{ref} is a reference current measured during the fault,
Iₘ is a fault current measured during a the fault, and
x_{c} is a characteristic relative impedance per unit of length.

45. The system of claim 40 wherein the processor further models one of the at least one feeder as including a first segment and a second segment, the first segment having a characteristic relative impedance and the second segment having a characteristic relative impedance per unit of length.

46. The system of claim 45 wherein the processor models one of the at least one feeder according to:
$$[ \begin{matrix}{X}_{o , relative} \\ {x}_{c} d\end{matrix} ] = {[ 1 \vert m ]}^{( + )} Re \{ {I}_{ref} / {I}_{m} \}$$
where m is a matrix of relative distances of test faults on feeder segments,
the superscript (+) indicates a pseudo-inverse operation,
I_{ref} is a matrix of reference currents measured during a test fault,
Iₘ is a matrix of fault currents measured during a test fault,
X_{o,relative} is the characteristic relative impedance of the first segment,
x_{c} is the characteristic relative impedance per unit of length of the second segment,
d is a distance of a feeder segment,
and x_{c} and X_{o,relative} are determined according to a least-square error criterion.

47. The system of claim 46 wherein the processor further determines a fault location according to:
$${m}_{f} d ≅ \frac{Re \{ {I}_{ref} / {I}_{m} \} - {X}_{o}}{{x}_{c}}$$
where
d is a distance of a feeder segment having a fault,
mf is a relative distance of the fault on the faulted feeder segment,
I_{ref} is a reference current measured during the fault,
Iₘ is a fault current measured during a the fault,
x_{c} is a characteristic relative impedance per unit of length of the second segment, and
X₀ is a characteristic relative impedance of the first segment.

48. The system of claim 40 wherein the power distribution system includes forked feeders, and the processor further models one of the at least one feeder as having a characteristic relative impedance and the other feeders as having a characteristic relative impedance per unit of length.

49. The system of claim 48 wherein the processor further models one of the at least one feeder as having a characteristic relative impedance and the other feeders as having a characteristic relative impedance per unit of length according to:
$$[ \begin{matrix}{X}_{o} \\ {d}_{1} {x}_{c1} \\ ⋮ \\ {d}_{4} {x}_{c4}\end{matrix} ] = {[ 1 \vert {m}_{Line1} \vert {m}_{Line2 } … \vert {m}_{Line4} ]}^{( + )} Re \{ {I}_{ref} / {I}_{m} \}$$
Xₒ is the characteristic relative impedance of the first feeder.
where x_{cq} is the characteristic relative impedance per unit of length of the q-th feeder,
d_{q} is the distance of the q-th feeder,
m is a matrix of relative distances of test faults,
the superscript (+) indicates a pseudo-inverse operation,
I_{ref} is a matrix of reference currents measured during a test fault,
Iₘ is a matrix of fault currents measured during a test fault,
and x_{cq} and Xₒ are determined according to a least-square error criterion.

50. The system of claim 26 wherein the processor further models the power distribution system with a loop equation for each of the at least one feeder, and determines a fault location by using a least-squared error criterion.

51. A computer-readable medium having instructions stored thereon for locating a fault in a power distribution system having a line frequency, the power distribution system including a plurality of phases, the power distribution system including at least one feeder, each feeder including at least one segment, the instructions, when executed on a processor, causing the processor to perform the following:
detecting a faulted phase from the plurality of phases of the power distribution system;
commanding a signal generator to inject a measurement signal having a measurement frequency into the detected faulted phase, the measurement frequency being a different frequency than the line frequency; and
determining a fault location for a selected segment based on at least one measured residual current corresponding to the injected signal and a predetermined relative impedance of the power distribution system.

52. The computer-readable medium of claim 51 wherein the processor further performs detecting a faulted phase further comprises detecting a faulted phase based on detecting a low phase-to-ground voltage.

53. The computer-readable medium of claim 51 wherein the processor further performs:
receiving a measured first phase-to-ground voltage for a first phase of the plurality of phases;
receiving a measured second phase-to-ground voltage for a second phase of the plurality of phases; and
determining a faulted phase as the first phase if the first phase-to-ground voltage is less than a predetermined minimum voltage and the second phase-to-ground voltage is greater than a predetermined maximum voltage.

54. The computer-readable medium of claim 53 wherein the predetermined minimum voltage V_{MIN-Threshold} is determined by:
V_{MIN-Threshold}=V_{MIN-SETTING}×|V_{MIN}|

where V_{MIN-SETTING} is about 0.1,

|V_{MIN}|=min(|V_{AB}|, |V_{BC}|, |V_{AC}|),
where V_{AB} is a measured voltage from phase A to phase B,
V_{BC} is a measured voltage from phase B to phase C, and
V_{AC} is a measured voltage from phase A to phase C.

55. The computer-readable medium of claim 53 wherein the predetermined maximum voltage V_{MAX-Threshold} is determined by:
V_{MAX-Threshold}=V_{MAX-SETTING}×|V_{MAX}|

where V_{MAX-SETTING} is about 0.85,

|V_{MAX}|=max(|V_{AB}|, |V_{BC}|, |V_{AC}|),
where V_{AB} is a measured voltage from phase A to phase B,
V_{BC} is a measured voltage from phase B to phase C, and
V_{AC} is a measured voltage from phase A to phase C.

56. The computer-readable medium of claim 51 wherein the processor further commands an injection of a measurement signal from about one ampere to about twenty amperes of current at a measurement frequency of between about 100 Hz and about 10,000 Hz into the faulted phase of the power distribution system.

57. The computer-readable medium of claim 51 wherein the processor further commands an injection of a measurement signal of about five ampere current signal at a measurement frequency of about 600 Hz for less than a second into the faulted phase of the power distribution system.

58. The computer-readable medium of claim 51 wherein the power distribution system is a looped power distribution system and each feeder includes a sending node and a receiving node, and the processor further performs:
determining a faulted feeder from the at least one feeder based on the injected measurement signal; and
selecting the determined fault location if the determined fault location is within a predetermined range.

59. The computer-readable medium of claim 58 wherein the processor further performs:
receiving a first measured residual current, for a selected feeder of the at least one feeder, the first measured residual current corresponding to the current from the sending node to the selected feeder and receiving a second measured residual current, for the selected feeder, the second measured residual current corresponding to the current from the receiving node to the selected feeder;
summing the first measured residual current and the second measured residual current; and
determining the selected feeder as the faulted feeder if the summed residual currents are greater than a predetermined current.

60. The computer-readable medium of claim 58 wherein processor further performs digital filtering of the first measured residual current and the second measured residual current, the filtering corresponding to the measurement frequency.

61. The computer-readable medium of claim 58 wherein the processor further performs:
modeling feeders of the at least one feeder that are not determined as a faulted feeder as an equivalent feeder at the measurement frequency;
modeling the selected segment as having a first impedance of m*Z and a second impedance of (1−m)*Z, where m is the relative distance of the fault location on the selected segment, and Z is the impedance of the selected segment;
modeling the power distribution system with at least one loop equation for the modeled equivalent feeder and the modeled selected segment; and
determining a fault location based on the at least one loop equation and the relative distance.

62. The computer-readable medium of claim 58 wherein the processor further performs selecting the determined fault location based on a predetermined range representing a full distance of the selected segment.

63. The computer-readable medium of claim 62 wherein the predetermined range is from zero to one.

64. The computer-readable medium of claim 51 wherein the power distribution system is a radial power distribution system, each feeder includes one segment, and each feeder includes a sending node, and the processor further performs:
commanding a connection of a reference impedance from the sending node to ground upon the commanding an injection of the measurement signal.

65. The computer-readable medium of claim 64 wherein the processor further performs:
receiving a first measured current from the residual current measuring device, the first measured current corresponding to current in the reference impedance;
receiving a second measured current from the residual current measuring device, the second measured current corresponding to a fault current; and
determining a fault location according to:
$$md = \frac{Re \{ \frac{{I}_{REF}}{{I}_{F}} \} - {X}_{o , relative}}{{x}_{c , relative}}$$
where d is the length of a faulted feeder segment,
m is location of the fault given in percentage of distance along the faulted feeder segment,
I_{REF} is the measured current in the reference impedance,
I_{F} is the measured fault current,
Re{I_{REF}/I_{F}} is the real part of the ratio of I_{REF} to I_{F},
X₀ is a constant reactance term,
x_{c} is a reactance per unit of distance,
X_{o,relative} is the ratio of X₀ to X_{REF},
X_{c,relative} is the ratio of x_{c} to X_{REF}, and
X_{REF} is the reactance of the reference impedance.

66. The computer-readable medium of claim 64 wherein the processor further performs:
modeling one of the at least one feeder as having a characteristic relative impedance per unit of length.

67. The computer-readable medium of claim 66 wherein the processor further performs modeling one of the at least one feeder as having a characteristic relative impedance per unit of length according to:
x_{c}=(1/d)m⁽⁺⁾Re{I_{ref}/Iₘ}
where x_{c} is the characteristic relative impedance per unit of length,
d is a distance of a feeder segment having a test fault,
m is a matrix of relative distances of test faults on feeder segments,
the superscript (+) indicates a pseudo-inverse operation,
I_{ref} is a matrix of reference currents measured during a test fault,
Iₘ is a matrix of fault currents measured during a test fault, and
x_{c} is determined according to a least-square error criterion.

68. The computer-readable medium of claim 67 wherein the processor further performs determining a fault location according to:
$${m}_{f} d ≅ \frac{Re \{ {I}_{ref} / {I}_{m} \}}{{x}_{c}}$$
where d is a distance of a feeder segment having a fault,
mf is a relative distance of the fault on the faulted feeder segment,
I_{ref} is a reference current measured during the fault,
Iₘ is a fault current measured during a the fault, and
x_{c} is a characteristic relative impedance per unit of length.

69. The computer-readable medium of claim 64 wherein the processor further performs:
modeling one of the at least one feeder as including a first segment and a second segment, the first segment having a characteristic relative impedance and the second segment having a characteristic relative impedance per unit of length.

70. The computer-readable medium of claim 69 wherein the processor further performs modeling one of the at least one feeder according to:
$$[ \begin{matrix}{X}_{o , relative} \\ {x}_{c} d\end{matrix} ] = {[ 1 \vert m ]}^{( + )} Re \{ {I}_{ref} / {I}_{m} \}$$
where m is a matrix of relative distances of test faults on feeder segments,
the superscript (+) indicates a pseudo-inverse operation,
I_{ref} is a matrix of reference currents measured during a test fault,
Iₘ is a matrix of fault currents measured during a test fault,
X_{o,relative} is the characteristic relative impedance of the first segment,
x_{c} is the characteristic relative impedance per unit of length of the second segment,
d is a distance of a feeder segment,
and x_{c} and X_{o,relative} are determined according to a least-square error criterion.

71. The computer-readable medium of claim 70 wherein the processor further performs determining a fault location according to:
$${m}_{f} d ≅ \frac{Re \{ {I}_{ref} / {I}_{m} \} - {X}_{o}}{{x}_{c}}$$
where
d is a distance of a feeder segment having a fault,
mf is a relative distance of the fault on the faulted feeder segment,
I_{ref} is a reference current measured during the fault,
Iₘ is a fault current measured during a the fault,
x_{c} is a characteristic relative impedance per unit of length of the second segment, and
X₀ is a characteristic relative impedance of the first segment.

72. The computer-readable medium of claim 64 wherein the power distribution system includes forked feeders, and the processor further performs:
modeling one of the at least one feeder as having a characteristic relative impedance and the other feeders as having a characteristic relative impedance per unit of length.

73. The computer-readable medium of claim 72 wherein the processor further performs modeling one of the at least one feeder as having a characteristic relative impedance and the other feeders as having a characteristic relative impedance per unit of length according to:
$$[ \begin{matrix}{X}_{o} \\ {d}_{1} {x}_{c1} \\ ⋮ \\ {d}_{4} {x}_{c4}\end{matrix} ] = [ 1 \vert {m}_{Line1} \vert {m}_{Line2} … {\vert {m}_{Line4} ]}^{( + )} Re \{ {I}_{ref} / {I}_{m} \}$$
Xₒ is the characteristic relative impedance of the first feeder.
where x_{cq} is the characteristic relative impedance per unit of length of the q-th feeder,
d_{q} is the distance of the q-th feeder,
m is a matrix of relative distances of test faults,
the superscript (+) indicates a pseudo-inverse operation,
I_{ref} is a matrix of reference currents measured during a test fault,
Iₘ is a matrix of fault currents measured during a test fault,
and X_{cq} and Xₒ are determined according to a least-square error criterion.

74. The computer-readable medium of claim 51 wherein the processor further performs:
modeling the power distribution system with a loop equation for each of the at least one feeder; and
determining a fault location by using a least-squared error criterion.
